(19) United States
(12) Patent Application Publication
(10) Pub. No.: US 2011/0255226 A1
(43) Pub. Date: Oct. 20, 2011

(54) Electrical Accessory and Method of Providing Same

(75) Inventors: Oliver Duncan Seil, Pasadena, CA (US); Vincent Razo, Granada Hills, CA (US); Thorben Neu, Los Angeles, CA (US); Chad DeJong, Los Angeles, CA (US); David A. Kleeman, Marina del Rey, CA (US); Vijendra Nalwad, Newbury Park, CA (US); Jungman Park, Altadena, CA (US); Steven Lane, Orange, CA (US)

(73) Assignee: Belkin International, Inc., Playa Vista, CA (US)

(21) Appl. No.: 13/089,141

(22) Filed: Apr. 18, 2011

Related U.S. Application Data
(63) Continuation-in-part of application No. 12/545,017, filed on Aug. 20, 2009.
Application No. 12/545,017 is a continuation of application No. 12/349,505, filed on Jan. 6, 2009.
Application No. 12/349,505 is a continuation-in-part of application No. 10/936,356, filed on Sep. 8, 2004, now Pat. No. 7,292,881.
Application No. 10/936,356 is a continuation-in-part of application No. 11/248,762, filed on Oct. 11, 2005, now Pat. No. 7,734,256.
Application No. 11/248,762 is a continuation-in-part of application No. 12/171,220, filed on Jul. 10, 2008, now Pat. No. 7,930,006.
Application No. 12/171,220 is a continuation of application No. 11/842,921, filed on Aug. 21, 2007, now Pat. No. 7,930,004.
Application No. 11/842,921 is a continuation of application No. 10/936,356, filed on Sep. 8, 2004, now Pat. No. 7,292,881.
(60) Provisional application No. 60/959,057, filed on Jul. 10, 2007.

(51) Int. Cl. H05K 7/00; F16M 13/00; B23P 11/00; F16B 47/00

(52) U.S. Cl. 361/679.01; 248/206.1; 211/26; 29/428

(57) ABSTRACT

Some embodiments disclose a coupling device configured to couple to a surface. The coupling device including: (a) a first housing; (b) a rotational dial with a first aperture and mechanically coupled to the first housing, the rotational dial comprising a cam mechanism adjacent to the first aperture; (c) a support base comprising a first stem with a second aperture, the first stem is located inside the first aperture, the stem having a second aperture; (d) a suction cup coupled to at least one of the rotational dial or the support base, the suction cup having: (1) a suction portion; and (2) a second stem located inside of the second aperture; and (e) an elastic mechanism located at least partially between the support base and the second stem of the suction cup. The coupling device is configured such that the suction cup can be rotated relative to at least the rotational dial to create a vacuum between the suction portion and the surface. Other embodiments are disclosed herein.

### CROSS-REFERENCE TO RELATED APPLICATIONS

This application is a continuation-in-part of U.S. patent application Ser. No. 12/545,017, filed Aug. 20, 2009, which is continuation of U.S. patent application Ser. No. 12/349,505, filed Jan. 6, 2009. U.S. patent application Ser. No. 12/349,505 is a continuation-in-part of U.S. patent application Ser. No. 10/936,356, now U.S. Pat. No. 7,292,881, filed Sep. 8, 2004 and a continuation-in-part of U.S. patent application Ser. No. 11/248,762, now U.S. Pat. No. 7,734,256, filed Oct. 11, 2005.

This application is also continuation-in-part of U.S. patent application Ser. No. 12/171,220, filed Jul. 10, 2008, which is a continuation of U.S. patent application Ser. No. 11/842,921, filed Aug. 21, 2007, which is a continuation of U.S. patent application Ser. No. 10/936,356, now U.S. Pat. No. 7,292,881, filed Sep. 8, 2004. U.S. patent application Ser. No. 12/171,220 also claims priority from U.S. Provisional Application No. 60/959,057, filed Jul. 10, 2007.

U.S. Pat. Nos. 7,292,881 and 7,734,256, U.S. patent application Ser. Nos. 12/545,017, 12/349,505, 12/171,220, and 11/842,921, and U.S. Provisional Application No. 60/959,057 are incorporated herein by reference.

### FIELD OF THE INVENTION

This invention relates to accessories for electrical devices, particularly media players (e.g., portable MP3 players). More specifically, the invention relates to an electrical device with supports for holding media players and a method of using the same.

### DESCRIPTION OF THE BACKGROUND

Numerous types of electrical devices are portable, such as, for example, mobile (or cellular) telephones, laptop computers, audio playback devices, AM (amplitude modulated) and FM (frequency modulated) radios, CD (compact disk) players, and MP3 (MPEG Audio Layer-3) players. The terms “electrical device” and “media player” should be broadly understood and include electrical devices of all types and designs (e.g., MP3 players and audio-visual media players). There are many portable electrical devices available, including those manufactured by Sony Corp., Philips Corp., Audiovox Corp., Microsoft Corp., Research-in-Motion, Inc. (e.g., the Blackberry® device), and Apple Computer, Inc. (e.g., iPod® MP3 player, iPhone™ device and iPad™ device).

A common problem with electrical accessories is that the accessories are designed to be compatible with only one or a very limited number of electrical devices. That is, an electrical accessory designed to work with the Apple iPod® MP3 player is not compatible with the Apple iPod® Mini MP3 player, the Apple iTouch® MP3 player, the Research-in-Motion Blackberry® device, or the Apple iPhone®. Usually, the incompatibility is caused by the inability of the electrical accessory to physically couple to the second electrical device. For example, the second MP3 player could be wider and/or thicker than the first electrical device, and a holder might not be designed to couple to electrical device that are wider and/or thicker than the first MP3 player. Furthermore, ever if the holder is designed to work with more than one size of MP3 player, the holder usually cannot physically couple to the MP3 player when the MP3 player is enclosed within a protective case.

Accordingly, a need exists for an apparatus or electrical accessory that overcomes the limitations of the prior art accessories for electrical devices.

### BRIEF DESCRIPTION OF THE DRAWINGS

To facilitate further description of the embodiments, the following drawings are provided in which:

FIG. 1 illustrates an isometric view of an electrical accessory, according to a first embodiment;

FIG. 2 illustrates a side view of the electrical accessory of FIG. 1 coupled to an electrical device, according to the first embodiment;

FIG. 3 illustrates a partial isometric view of the electrical accessory of FIG. 1 with a cover removed, according to the first embodiment;

FIG. 4 illustrates a back isometric view of an arm and a support of the electrical accessory of FIG. 1, according to the first embodiment;

FIG. 5 illustrates an isometric view of the electrical accessory of FIG. 1 with the arm and the support of FIG. 4 removed, according to the first embodiment;

FIG. 6 illustrates an isometric view of an electrical accessory, according to a second embodiment;

FIG. 7 illustrates a side view of the electrical accessory of FIG. 6, according to the second embodiment;

FIG. 8 illustrates an isometric view of the electrical accessory of FIG. 6 holding the electrical device of FIG. 2, according to a second embodiment;

FIG. 9 illustrates a front perspective view of a holder for an electrical device, according to a third embodiment;

FIG. 10 illustrates a front perspective view of the holder of FIG. 9 coupled to an electrical device, according to the third embodiment;

FIG. 11 illustrates an isometric view of an electrical accessory, according to a fourth embodiment;

FIG. 12 illustrates an isometric view of a portion of the electrical accessory of FIG. 11 coupled to an electrical interface, according to the fourth embodiment;

FIG. 13 is an isometric view of another portion of the electrical accessory of FIG. 11 coupled to the electrical interface of FIG. 12 and the electrical device of FIG. 10, according to the fourth embodiment;

FIG. 14 illustrates an exploded view of an example of a cradle section of the electrical accessory of FIG. 11 with the electrical interface of FIG. 12, according to the fourth embodiment;

FIG. 15 illustrates an isometric view of an electrical accessory, according to a fifth embodiment;

FIG. 16 illustrates an isometric view of an electrical accessory, according to a sixth embodiment;

FIG. 17 illustrates a side view of a portion of the electrical accessory of FIG. 16, according to the sixth embodiment;

FIG. 18 illustrates an isometric view of the electrical accessory of FIG. 16 holding the electrical device of FIG. 2, according to the sixth embodiment;

FIG. 19 illustrates an isometric view of an electrical accessory, according to a seventh embodiment;

FIG. 20 illustrates another isometric view of the electrical accessory of FIG. 19 and a hand of a user of an electrical device, according to the seventh embodiment;

FIG. 21 illustrates an isometric view of a portion of the electrical accessory of FIG. 19 holding the electrical device of FIG. 2, according to the seventh embodiment;

FIG. 22 illustrates an isometric view of a gear mechanism of the electrical accessory of FIG. 19, according to the seventh embodiment;

FIG. 23 illustrates an isometric view of an electrical accessory, according to an eighth embodiment;

FIG. 24 illustrates an isometric view of the electrical accessory of FIG. 23 holding an electrical device, according to the eighth embodiment;

FIG. 25 illustrates an isometric view of a gear mechanism of the electrical accessory of FIG. 23, according to the eighth embodiment;

FIG. 26 illustrates an isometric view of a portion of an electrical accessory, according to a ninth embodiment;

FIG. 27 illustrates a side view of the electrical accessory of FIG. 26, according to the ninth embodiment;

FIG. 28 illustrates a cut-away view of a power acquisition unit of the electrical accessory of FIG. 26 along line 28-28 (FIG. 26), according to the ninth embodiment;

FIG. 29 illustrates a rear view of an electrical module of the electrical accessory of FIG. 26, according to the ninth embodiment;

FIG. 30 illustrates an isometric view of a portion of a cigarette lighter module of the electrical accessory of FIG. 26, according to the ninth embodiment;

FIG. 31 illustrates an isometric view of an electrical accessory, according to a tenth embodiment;

FIG. 32 illustrates another isometric view of the electrical accessory of FIG. 31, according to the tenth embodiment;

FIG. 33 illustrates an isometric view of a portion of an electrical accessory, according to an eleventh embodiment;

FIG. 34 illustrates a front view of a coupling mechanism in a locked position, according to a twelfth embodiment;

FIG. 35 illustrates a front view of the coupling mechanism of FIG. 34 in an unlocked position, according to the twelfth embodiment;

FIG. 36 illustrates an exploded view of the coupling mechanism of FIG. 34, according to the twelfth embodiment;

FIG. 37 illustrates a top, back isometric view of a rotational dial of the coupling mechanism of FIG. 34, according to the twelfth embodiment;

FIG. 38 illustrates a bottom, back isometric view of the rotational dial of the coupling mechanism of FIG. 34, according to the twelfth embodiment;

FIG. 39 illustrates a flow chart for an embodiment of a method of providing an electrical accessory for holding two or more electrical devices, according to an embodiment; and

FIG. 40 illustrates a flow chart for an embodiment of activity of providing a connection mechanism of the method of FIG. 34, according to an embodiment.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein.

The terms “couple,” “coupled,” “couples,” “coupling,” and the like should be broadly understood and refer to connecting two or more elements or signals, electrically, mechanically and/or otherwise. Two or more electrical elements may be electrically coupled but not be mechanically or otherwise coupled; two or more mechanical elements may be mechanically coupled, but not be electrically or otherwise coupled; two or more electrical elements may be mechanically coupled, but not be electrically or otherwise coupled. Coupling may be for any length of time, e.g., permanent or semi-permanent or only for an instant.

“Electrical coupling” and the like should be broadly understood and include coupling involving any electrical signal, whether a power signal, a data signal, and/or other types or combinations of electrical signals. “Mechanical coupling” and the like should be broadly understood and include mechanical coupling of all types.

The absence of the word “removably,” “removable,” and the like near the word “coupled,” and the like does not mean that the coupling, etc. in question is or is not removable.

### DETAILED DESCRIPTION OF EXAMPLES OF EMBODIMENTS

Some embodiments disclose a coupling device configured to couple to a surface. The coupling device including: (a) a first housing; (b) a rotational dial with a first aperture and mechanically coupled to the first housing, the rotational dial comprising a cam mechanism adjacent to the first aperture; (c) a support base comprising a first stem with a second aperture, the first stem is located inside the first aperture, the first stem having a second aperture; (d) a suction cup coupled to at least one of the rotational dial or the support base, the suction cup having: (1) a suction portion; and (2) a second stem located inside of the second aperture; and (e) an elastic mechanism located at least partially between the support base and the second stem of the suction cup. The coupling device is configured such that the rotational dial can be rotated relative to at least suction cup the to create a vacuum between the suction portion of the suction cup and the surface.

Some embodiments disclose an electrical accessory for holding two or more electrical devices. Each of the two or more electrical devices has a top side and a bottom side opposite the top side. The electrical accessory can include a holder configured to couple to the two or more electrical devices. The holder can have: (1) a cradle section configured to removably couple to the bottom side of the two or more electrical devices; (2) a first arm coupled to the cradle section; (3) a second arm movably coupled to the first arm; and (4) a first support coupled to the second arm and configured to couple to the top side of the two or more electrical devices. A length of the holder can be a distance between the cradle section and the first support. The holder can be configured such that the length of the holder is changed by moving the second arm relative to the first arm. The length of the holder can be substantially equal to a length of a first electrical device of the two or more electrical devices when the holder is removably coupled to the first electrical device of the two or more electrical devices. The length of the holder can be substantially equal to a length of a second electrical device of the two or more electrical devices when the holder is removably coupled to the second electrical device of the two or more electrical devices.

Various additional embodiments disclose an electrical accessory for holding two or more electrical devices. The electrical accessory can include a holder configured to couple to the two or more electrical devices. The holder can have: (1) a cradle section, the cradle section comprising an electrical coupling; (2) a first side support with a proximal end and a distal end opposite the proximal end of the first side support; (3) a second side support with a proximal end and a distal end opposite the proximal end of the second side support; (4) one or more gears coupled to the first side support and the second side support; and (5) an activation mechanism coupled to the one or more gears. The holder can be configured such that a first electrical device of the two or more electrical devices is held between the cradle section, the first side support, and the second side support when the holder is coupled to the first electrical device of the two or more electrical devices. The one or more gears can be configured such that a user uses the activation mechanism to turn the one or more gears and causes a distance between the distal end of the first side support and the distal end of the second side support to change.

Yet further embodiments disclose an electrical accessory for holding two or more electrical devices. Each of the two or more electrical devices has a top side and a bottom side opposite the top side. The electrical accessory can include a holder configured to couple to the two or more electrical devices. The holder can include: (1) a cradle section configured to couple to the bottom side of the two or more electrical devices; (2) a first arm coupled to the cradle section; (3) a first support coupled to the first arm and configured to couple to the top side of the two or more electrical devices; and (4) a stretch mechanism coupled to the cradle section and the first arm such that a compression force is applied to the top side and the bottom side of a first electrical device of the two or more electrical devices when the first electrical device of the two or more electrical devices is coupled to the holder.

In still yet other embodiments, an electrical accessory can include a body having: (1) a first module with one or more dimples; and (2) a second module with an indentation with a bump. At least one of the first module and the second module can have a magnet. The body can be configured such that the first module is removably coupled to the second module by coupling the indentation and the bump to one of the one or more dimples. The second module can include at least one of a display or controls for the electrical accessory.

Additional embodiments disclose a method of providing an electrical accessory for holding two or more electrical devices. The method can include: (a) providing a cradle section configured to couple to the two or more electrical devices at different times; (b) providing a connection mechanism; (c) providing a first support configured to removably couple to the two or more electrical devices; and (d) coupling the cradle section to the connection mechanism and the first support. A holder can include the cradle section, the connection mechanism, and the first support. A length of the holder can be a distance between the cradle section and the first support. In some examples, providing the connection mechanism can include: (a) providing a first arm; (b) providing a second arm; and (c) movably coupling the first arm to the second arm. In the same or different examples, coupling the cradle section to the connection mechanism and the first support can include coupling the cradle section to the connection mechanism and the first support such that the length of the holder is changed by moving the second arm relative to the first arm.

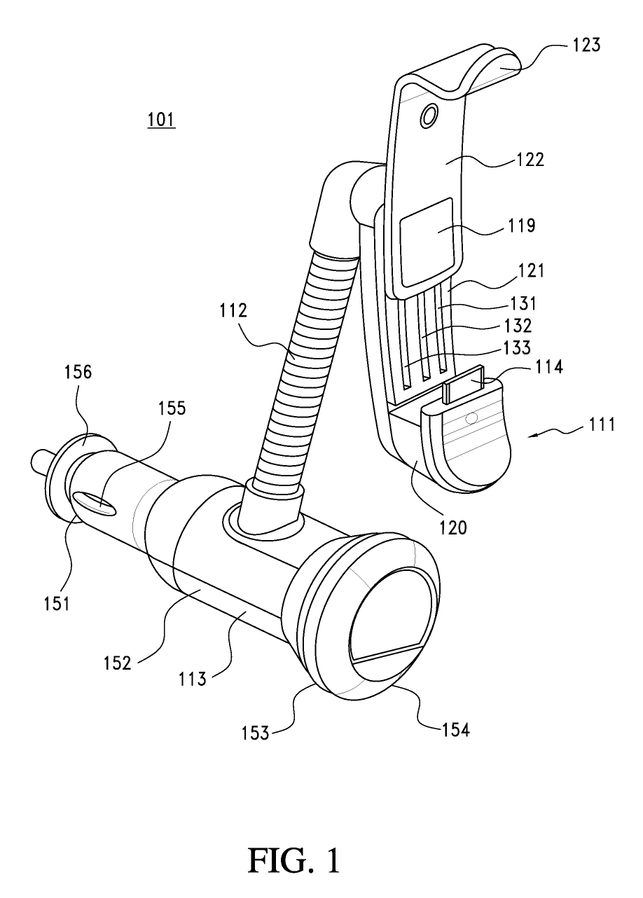

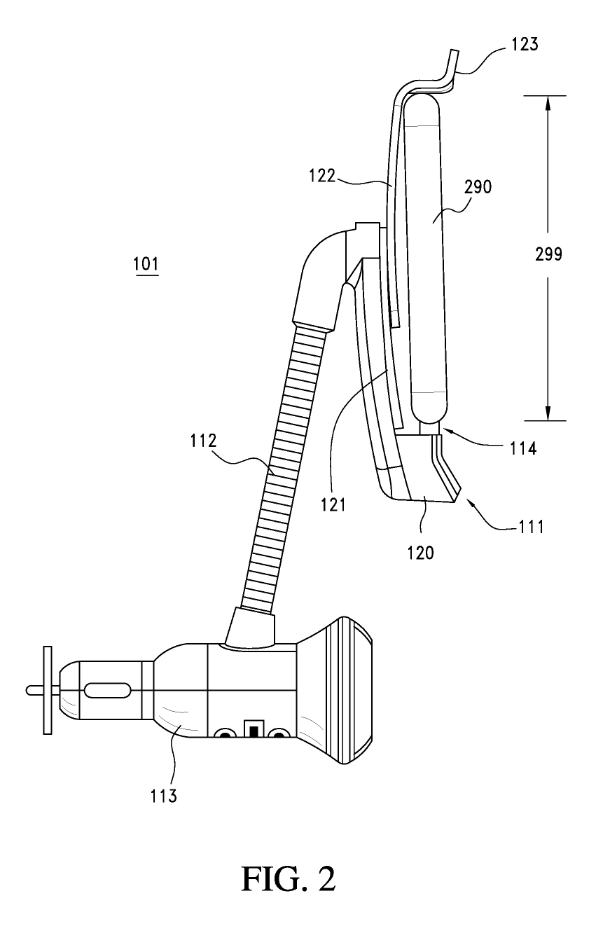

FIG. 1 illustrates an isometric view of electrical accessory 101, according to a first embodiment. FIG. 2 illustrates a side view of electrical accessory 101 coupled to an electrical device 290, according to the first embodiment. In some examples, electrical accessory 101 can be configured for holding two or more electrical devices at different times. In the same or different embodiment, electrical accessory 101 can be configured for coupling two or more electrical devices to an external power supply at different times. Electrical accessory 101 is merely exemplary and is not limited to the embodiments presented herein. Electrical accessory 101 can be employed in many different embodiments or examples not specifically depicted or described herein.

As illustrated in FIGS. 1-2, electrical accessory 101 can include: (a) a holder 111 configured to hold or couple to two or more electrical devices; (b) a connector 112; (c) a power acquisition unit 113 configured to receive electrical power from an external power source (e.g., a cigarette lighter); and (d) an electrical interface 114 configured to mechanically and electrically couple to the two or more electrical devices.

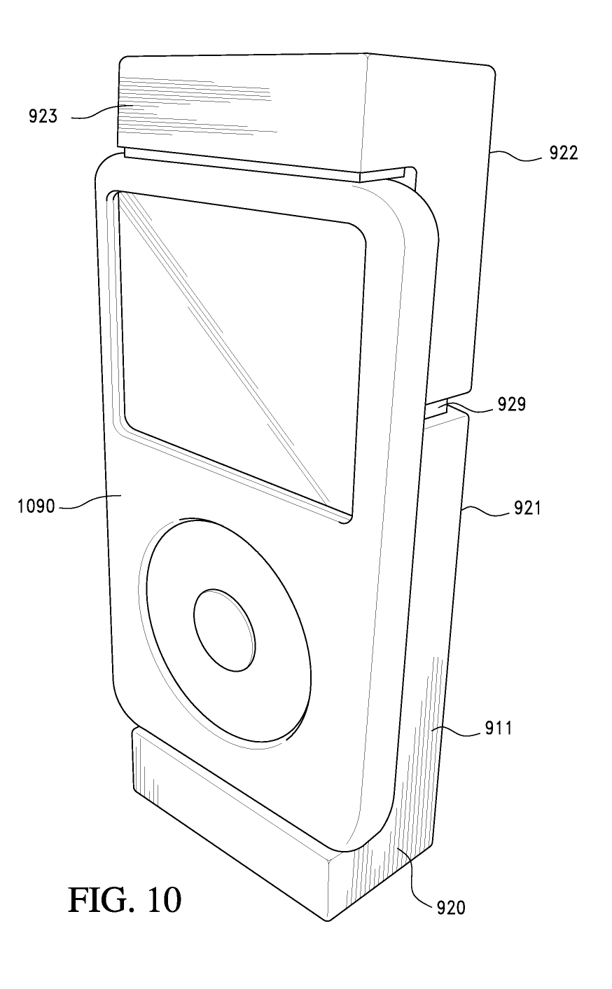

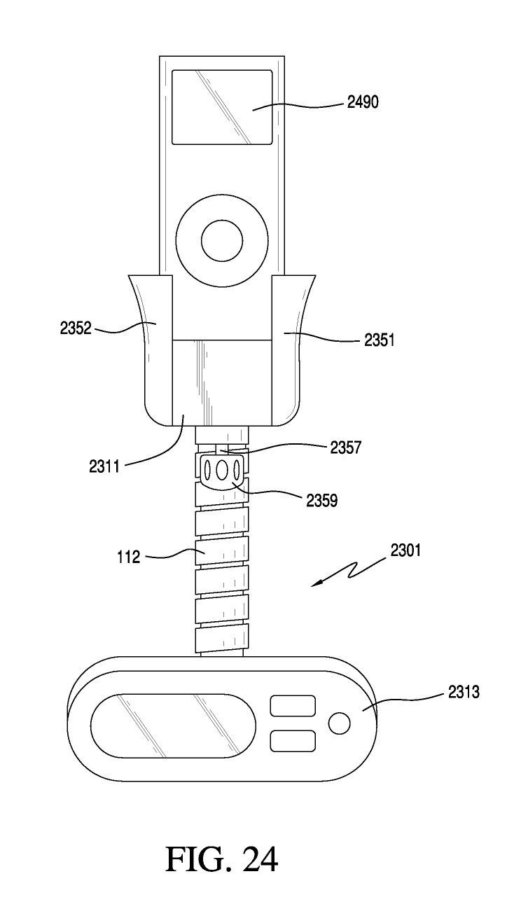

Holder 111 can include: (a) a cradle section 120 configured to couple to the bottom side of the two or more electrical devices (e.g., electrical device 290 (FIG. 2), electrical device 1090 (FIG. 10), and electrical device 2490 (FIG. 24)); (b) an arm 121 coupled to cradle section 120; (c) an arm 122 adjustably or movably coupled to arm 121; and (d) a support 123 coupled to arm 122 and configured to couple to the top side of the two or more electrical devices at different times. In some examples, electrical interface 114 protrudes from cradle section 120 and is configured to help hold the electrical devices to holder 111 by securing the electrical device to cradle section 120. In various examples, cradle section 120 can be considered to have a receptacle that permanently holds electrical interface 114.

A length of holder 111 is a distance between cradle section 120 and support 123 (e.g., distance 299 (FIG. 2)). Holder 111 is configured such that the length of holder 111 can be adjusted by moving arm 122 relative to arm 121. That is, the length of holder 111 can be adjusted depending on the length of the electrical device coupled to holder 111. For example, if a first media player has a first length and if a second media player has a second length, the length of holder 111 can be adjusted to be proportional to the first length when coupled to the first media player and can be adjusted to be proportional to the second length when coupled to the second media player. That is, when the first media player is electrical device 290, distance 299 between cradle section 120 and support 123 (i.e., the length of holder 111) is substantially equal to a length of electrical device 290 when electrical accessory 101 is holding electrical device 290. Similarly, the distance (not shown) between cradle section 120 and support 123 is substantially equal to a length of a second media player (e.g., electrical device 1090 (FIG. 10) or 2490 (FIG. 24)) when electrical accessory 101 is holding the second media player.

In some examples, holder 111 is rotatably coupled to connector 112. That is, holder 111 (and electrical device 290) can be rotated relative to connector 112 and power acquisition unit 113. In some examples, a point or region of holder 111 can be rotated clockwise or counterclockwise one hundred and eighty degrees relative to a point or region of connector 112 and a point or region of power acquisition unit 113.

Connector 112 can be a semi-rigid elongated portion configured to allow a position of holder 111 to be semi-permanently adjusted relative to a position of the power acquisition unit 113. In some examples, connector 112 can include a gooseneck, which can be compliant (or obedient) flexible tubing, and is preferably metallic or metal covered with, e.g., plastic or elastic material on its outside. A gooseneck can be considered to be a coiled layered construction in which adjacent coils overlap but can be moved with respect to each other (in a sense, slide on each other). Goosenecks tend to hold the position into which it is bent (i.e., it is semi-permanently adjustable or repositionable), unless it is bent beyond its limit. The two “layers” of the gooseneck can be considered to have different thicknesses. Thus, a gooseneck has two outer diameters, the outer diameter of the thicker layer, and the outer diameter of the thinner layer, which alternate in the gooseneck. In some embodiments, connector 112 can be between 7.5 centimeters (cm) and 15.2 cm (e.g., approximately 11.4 long cm); its larger outer diameter is approximately 9 millimeters (mm); its smaller outer diameter is approximately 8.2 millimeters; its inner diameter is approximately 4.5 millimeters; the center-to-center spacing between the larger diameter portions is approximately 3.5 millimeters; the longitudinal gap between the larger diameter portions is approximately 1 millimeter; and the material of construction can be steel.

Connector 112 must not be so stiff that it cannot be readily repositioned by the user; however, it must be stiff enough to maintain holder 111 (with electrical device 290) in position with respect to power acquisition unit 113 after holder 111 and connector 112 have been put into their desired position.

Connector 112 used in some embodiments are available in varying dimensions (e.g., outer diameters of 2 millimeters or less to over 16 millimeters). Connector 112 can be implemented with a design, dimensions, and materials of construction selected for any particular usage based on the desired length of connector 112, the weight of holder 111, the weight of electrical device 290 to be held in holder 111, whether connector 112 is to function as a broadcast antennas and if so, for what range of radio frequencies.

Power acquisition unit 113 includes: (a) an end portion 151; (b) a middle portion 152; and (c) an end portion 153. Connector 112 can be coupled to middle portion 152. In other examples, connector 112 can be coupled to end portion 151 or 153. In some examples, end portion 153 has a larger diameter than middle portion 152, and middle portion 152 has a larger diameter than end portion 151.

In numerous embodiments, an internal cavity exists inside of end portion 151, end portion 153, and middle portion 152. This internal cavity can contain the electrical circuitry for obtaining electrical power from an external power source such as a cigarette lighter and then processing the electrical power (i.e., the circuitry for cigarette lighter adapter). The internal cavity can also contain electrical circuitry for a transmitter (not shown) and transmitter controls 154. In some examples, power acquisition unit 113 is configured to couple to a cigarette lighter of a vehicle. That is, power acquisition unit 113 includes a cigarette lighter adapter.

End portion 151 can be configured to be inserted into an external power source such as the cigarette lighter of a vehicle, which is usually a cylindrical cavity. To help position and stabilize the power acquisition unit 113 in such a cavity, non-conductive stabilizing springs 155 are provided on opposite sides of end portion 153.

Because springs 155 may be insufficient to stabilize the electrical accessory 101 in all of the various size cigarette lighters that are found in vehicles, and particularly because of the cantilevered weight of electrical accessory 101, a stabilizer 156 can be used. Stabilizer 156 can include a deformable resilient member that is larger than the inner circumference of essentially all known vehicle cigarette lighters so that pushing end portion 151 into the cigarette lighter causes the outer circumference of the deformable resilient member to bend away from the distal end of end portion 151 (i.e., the part of end portion 151 farthest from middle portion 152) and towards the proximal end of end portion 153 (the part of end portion 153 closest to middle portion 152) while at least some of the deformable resilient member even after such deformation continues to push against the inner circumference of the cigarette lighter.

Stabilizer 156 allows power acquisition unit 113 to fit in the cigarette lighter of virtually any vehicle to mechanically and electrically, as well as semi-permanently (e.g., firmly but removably), couple electrical accessory 101 to keep power acquisition unit 113 in the desired position and maintain good electrical contact with the cigarette lighter. Stabilizer 156 retards or prevents undesired rotation, wobbling, and longitudinal movement of power acquisition unit 113 in the cigarette lighter. Thus, stabilizer 156 tends to prevent normal vibration, centrifugal forces (e.g., from the vehicle's turning), and bumps in the road from moving power acquisition unit 113 (and therefore electrical accessory 101) from its desired position.

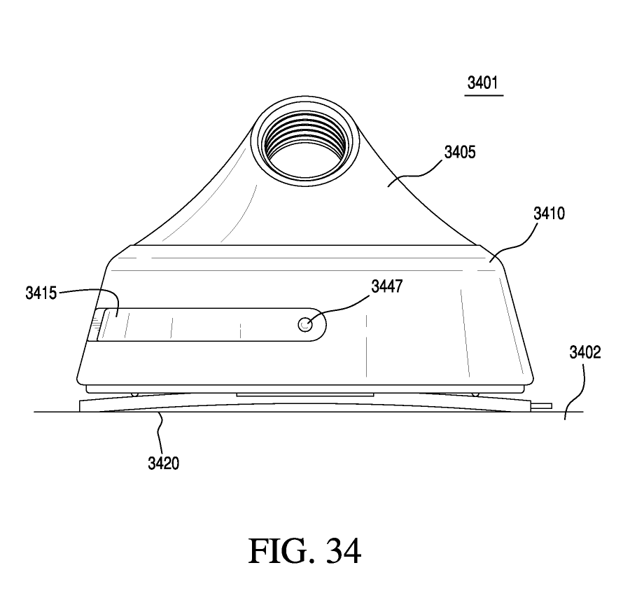

In other examples of power acquisition unit 101 (or any power acquisition unit discussed herein), power acquisition unit 113 is not configured to receive electrical power from an external power source. That is, power acquisition unit 113 is just a body coupled to connector 112. In these examples, instead of being configured to receive electrical power, power acquisition unit 113 can have a coupling mechanism (e.g., coupling mechanism 3401 of FIGS. 34-38 or a suction cup). The coupling mechanism can be configured to hold electrical accessory 101 to a relatively or substantially flat surface. For example, the coupling mechanism can couple to a dashboard or windshield of a vehicle, a window, or a tabletop.

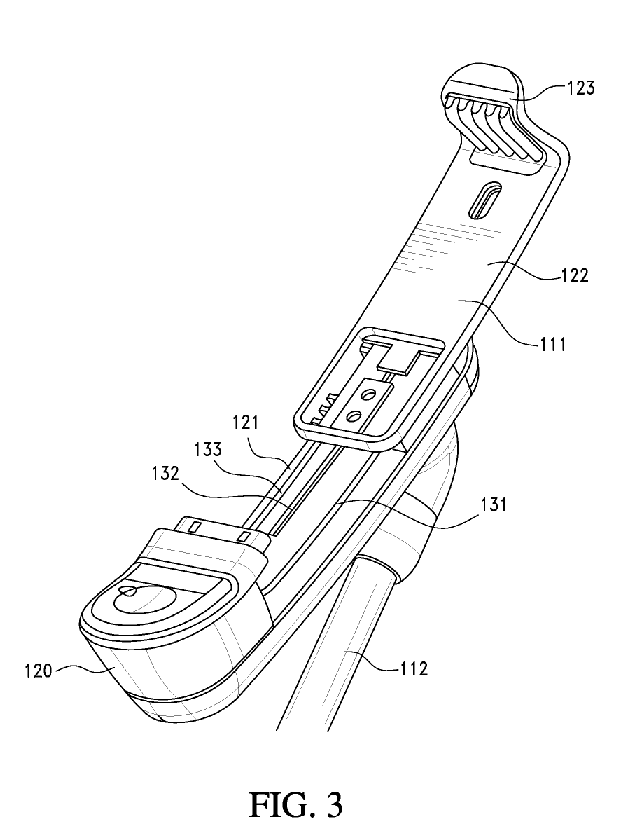

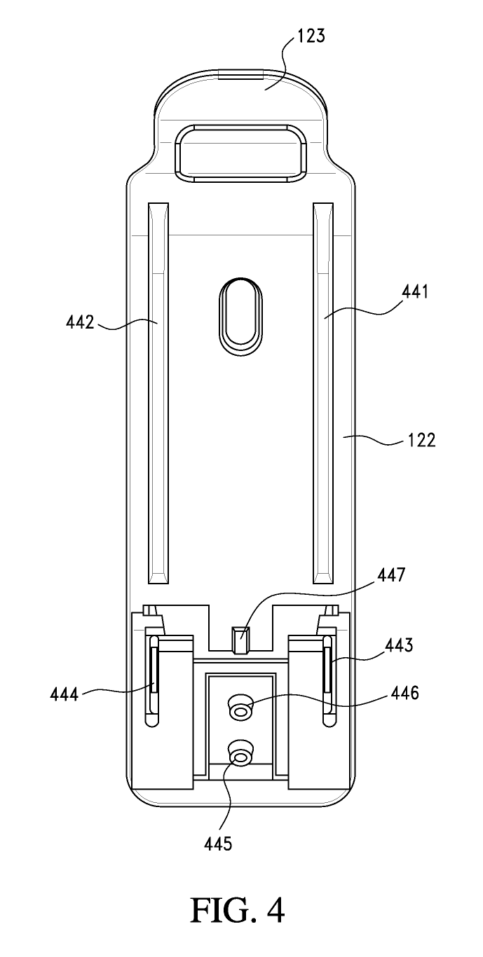

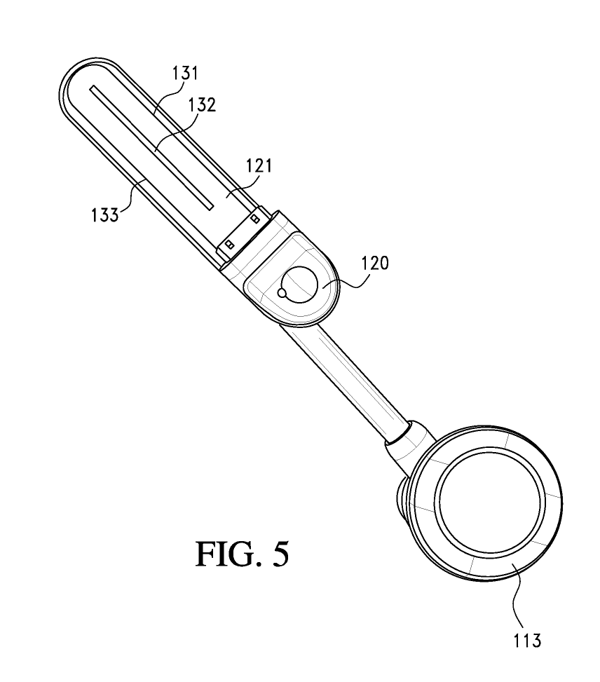

FIG. 3 illustrates a partial isometric view of electrical accessory 101 with cover 119 (FIG. 1) removed, according to the first embodiment. FIG. 4 illustrates a back isometric view of arm 122 and support 123, according to the first embodiment. FIG. 5 illustrates an isometric view of electrical accessory 101 with arm 122 and support 123 removed, according to the first embodiment.

FIGS. 3-5 illustrate an example of a system used to adjustably couple arm 121 to arm 122, according to the first embodiment. This system is merely exemplary and is not limited to the embodiments presented herein. The adjustable coupling system can be employed in many different embodiments or examples not specifically depicted or described herein.

Referring to FIGS. 3-5, arm 121 can include one or more grooves 131, 132, and 133. Arm 122 can include: (a) protrusions 441, 442, 443, and 444; and (b) pins 445, 446, and 447. Protrusions 442 and 444 can be placed in groove 131. Protrusions 441 and 443 can be placed in groove 133. Pins 445, 446, and 447 can be placed into groove 132. The length of holder 111 can be adjusted by moving protrusions 441-444 and pins 445-447 in grooves 131-133. In some examples, protrusions 441-444 and pins 445-447 fit snugly to grooves 131-133 to secure arm 121 to arm 122.

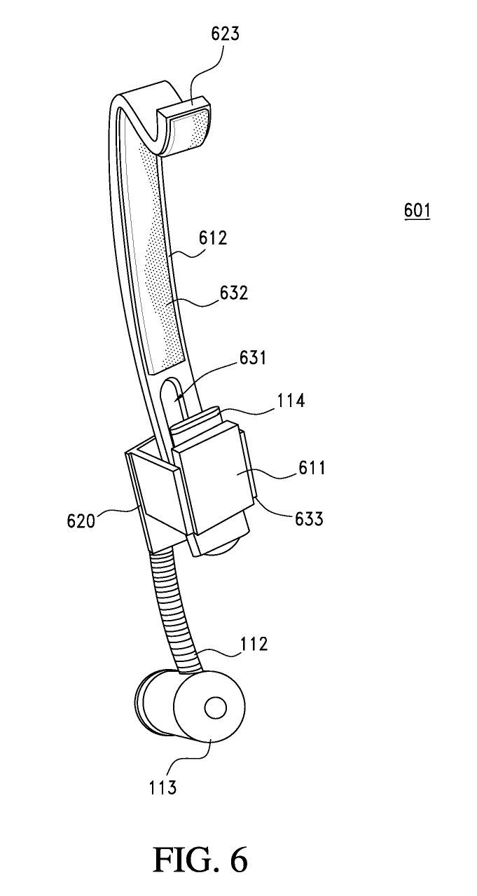

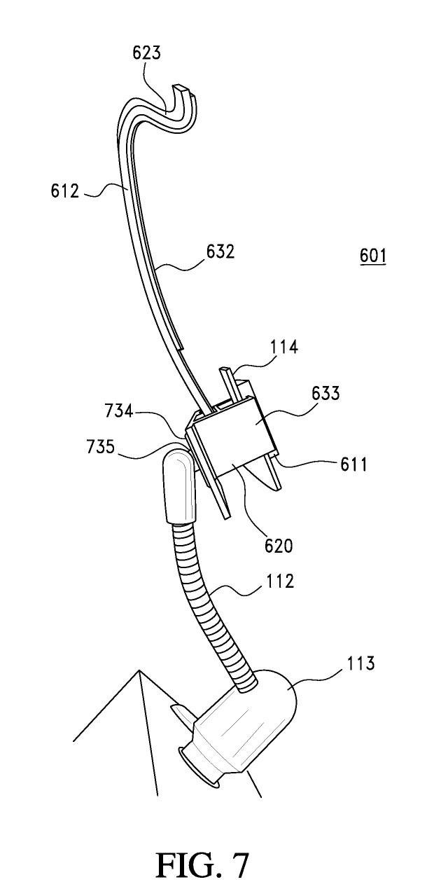

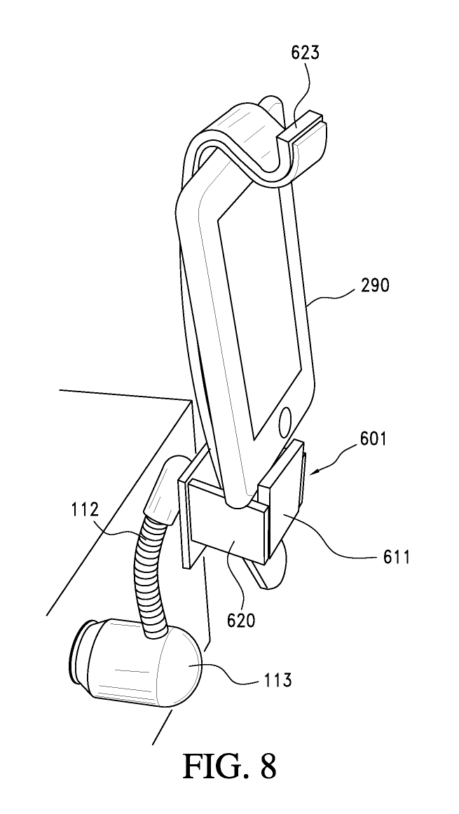

Turning to another embodiment, FIG. 6 illustrates an isometric view of electrical accessory 601, according to a second embodiment. FIG. 7 illustrates a side view of electrical accessory 601, according to the second embodiment. FIG. 8 illustrates an isometric view of electrical accessory 601 holding electrical device 290, according to the second embodiment. Electrical accessory 601 is merely exemplary and is not limited to the embodiments presented herein. Electrical accessory 601 can be employed in many different embodiments or examples not specifically depicted or described herein.

As illustrated in FIGS. 6-8, electrical accessory 601 can include: (a) a holder 611 configured to hold or couple to two or more electrical devices (e.g., electrical devices 290 (FIG. 8), 1090 (FIG. 10), or 2490 (FIG. 24)) at different times; (b) connector 112 coupled to holder 611; (c) power acquisition unit 113 configured to receive electrical power from an external power source (e.g., a cigarette lighter); and (d) electrical interface 114 configured to mechanically and electrically couple to two or more electrical devices.

Holder 611 can include: (a) a cradle section 620 configured to couple to the bottom side of the two or more electrical devices, cradle section 620 having an end 633 and an end 734 opposite end 633; (b) an arm 612 adjustably coupled to cradle section 620; and (c) a support 623 coupled to arm 612 and configured to couple to the top side of the electrical devices at different times. In some examples, electrical interface 114 protrudes from cradle section 620 and is configured to help hold the electrical device to holder 611 by securing the electrical device to cradle section 620. In the same or different embodiments, arm 612 can have padding 632 on at least a portion of arm 612 to prevent scratching of the electrical device.

Arm 612 can include a groove section 631 and cradle section 620 can include a snap section (not shown) that is complementary in size and shape to groove section 631. The length of holder 611 can be adjusted be moving groove section 631 along the snap section of cradle section 620. Cradle section 620 also can include a mechanism configured to allow some movement of arm 612 in the horizontal direction. That is, cradle section can be configured to allow some movement by arm 612 along an axis running between ends 633 and 734. In various examples, cradle section 620 can include one or more springs coupled between arm 612 and end 633 and/or 734 that allow for the movement in the horizontal direction.

In this embodiment, electrical device 290 can be inserted in holder 611 by coupling electrical device 290 to electrical interface 114 and pressing the top portion of electrical device 290 against support 623. Support 623 can be made from materials that provide sufficient flexible to allow the top of electric device 290 to be snapped into support 623. In some examples, hinge 735 coupling connector 112 to holder 611 can be locked in place to allow easier coupling of electrical device 290 and holder 611. In various embodiments, electrical accessory 601 can include a mechanism (not shown) configured to allow a user to lock hinge 735 in one or more predetermined positions.

To remove electrical device 290 from holder 611, the user can press (e.g., with his or her thumb) slightly upward against the front of support 623 to release the top portion of electrical device 290 from support 623. After support 623 is released, electrical device 290 can be pulled upwards out of holder 611 to remove electrical device 290 from electrical interface 114.

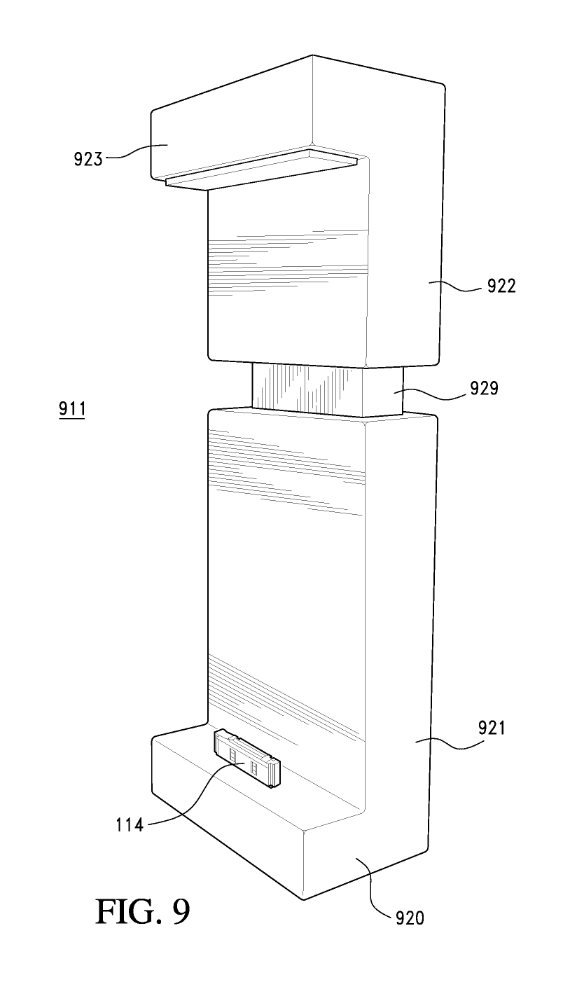

Turning to yet another embodiment, FIG. 9 illustrates a front perspective view of a holder 911 for an electrical device, according to a third embodiment. FIG. 10 illustrates a front perspective view of holder 911 coupled to electrical device 1090, according to the third embodiment. Holder 911 is merely exemplary and is not limited to the embodiments presented herein. Holder 911 can be employed in many different embodiments or examples not specifically depicted or described herein.

Holder 911 can include: (a) a cradle section 920 configured to couple to the bottom side of two or more electrical devices at different times; (b) a first arm 921 coupled to cradle section 920; (c) a second arm 922 adjustably coupled to first arm 921; (d) coupling portion 929; and (e) a support 923 coupled to second arm 922 and configured to couple to the top side of the two or more electrical devices at different times. In some examples, electrical interface 114 protrudes from cradle section 920 and is configured to help hold the electrical device to holder 911 by securing the electrical device to cradle section 920. Although not shown in FIG. 9 or 10, holder 911 can be coupled to connector 112 (FIGS. 1) and power acquisition unit 113 (FIG. 1) similar to the coupling of holder 111 (FIG. 1) to connector 112 (FIG. 1) and power acquisition unit 113 (FIG. 1).

The length of holder 911 can be adjusted based on the length of the electrical device coupled to holder 911. That is, if a first electrical device (e.g., electrical device 1090 (FIG. 10)) has a first length and a second electrical device (e.g., electrical device 290 (FIG. 2) or electrical device 2490 (FIG. 24)) has a second length, the length of holder 911 can be adjusted to be proportional to the first length when coupled to the first media player and proportional to the second length when coupled to the second electrical device.

In some examples, coupling portion 929 can couple first arm 921 to second arm 922. Coupling portion 929 can be located at least partially within first arm 921 and second arm 922. That is, a first part (not shown) of coupling portion 929 is located inside of first arm 921. A second part (not shown) of coupling portion 929 is located inside of second arm 922. In a different embodiment, coupling portion 929 is located inside only one of first arm 921 or second arm 922.

Coupling portion 929 couples first arm 921 to arm 922 such that the length of holder 911 can be changed by adjusting a length of the first part and/or a length of the second part. That is, the length of holder 911 is adjusted by changing the amount of coupling portion 929 located inside of either first arm 921 or second arm 922. For example, the length of holder 911 can be lengthened by sliding a larger portion of coupling portion 929 out of first arm 921 or second arm 922. The length of holder 911 can be decreased by increasing the portion of coupling portion 929 located inside first arm 921 or second arm 922.

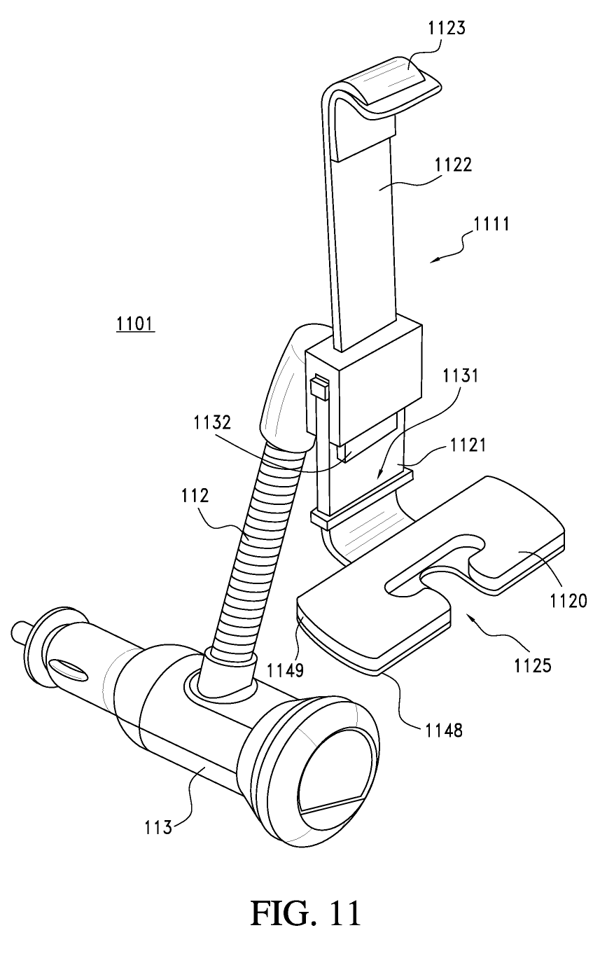

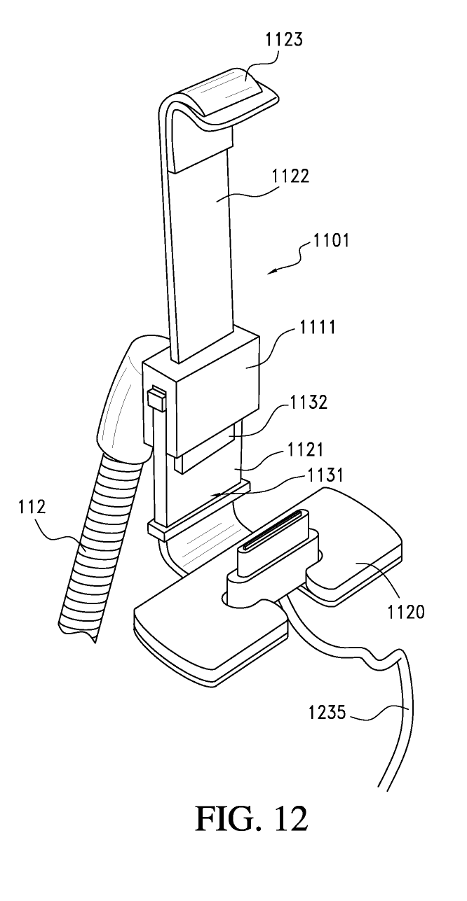

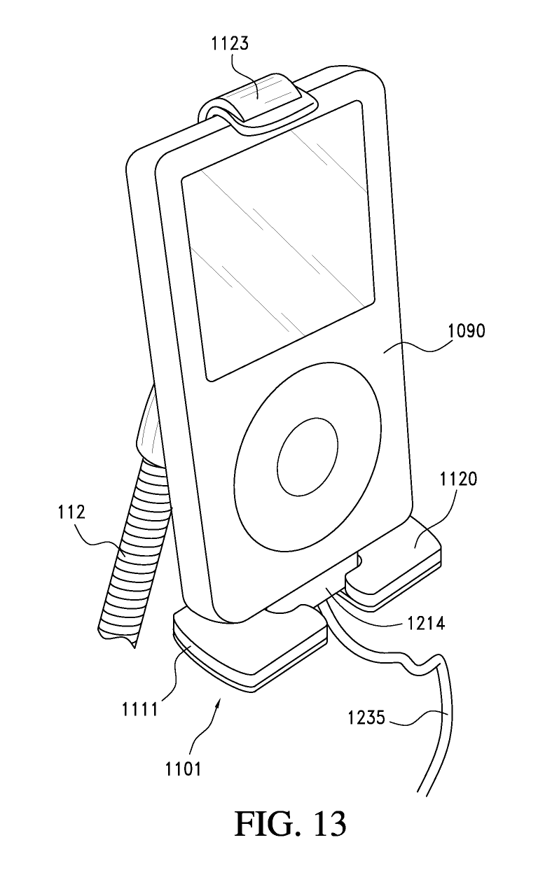

Turning to still another embodiment, FIG. 11 illustrates an isometric view of electrical accessory 1101, according to a fourth embodiment. FIG. 12 illustrates an isometric view of a portion of electrical accessory 1101 coupled to an electrical interface 1214, according to the fourth embodiment. FIG. 13 is an isometric view of another portion of electrical accessory 1101 coupled to electrical interface 1214 and electrical device 1090.

In some examples, electrical accessory 1101 can be configured to hold two or more electrical devices (e.g., electrical device 290 (FIG. 2), electrical device 1090 (FIG. 13), and electrical device 2490 (FIG. 24)) at different times. In the same or different embodiment, electrical accessory 1101 can be configured for coupling two or more electrical devices to an external power supply (e.g., a cigarette lighter). Electrical accessory 1101 is merely exemplary and is not limited to the embodiments presented herein. Electrical accessory 1101 can be employed in many different embodiments or examples not specifically depicted or described herein.

As illustrated in FIGS. 11-13, electrical accessory 1101 can include: (a) holder 1111 configured to hold or couple to electrical interface 1214 (FIG. 12) and two or more electrical devices at different times; (b) connector 112; and (c) power acquisition unit 113 configured to receive electrical power from an external power source (e.g., a cigarette lighter).

Holder 1111 can include: (a) a cradle section 1120 configured to couple to the bottom side of the two or more electrical devices (e.g., electrical device 1090 (FIG. 13), electrical device 290 (FIG. 2), and electrical device 2490 (FIG. 24)) at different times; (b) an arm 1121 coupled to cradle section 1120; (c) an arm 1122 adjustably coupled to arm 1121; and (d) a support 1123 coupled to arm 1122 and configured to couple to the top side of the two or more electrical devices at different times. In some examples, electrical interface 114 (FIG. 12) protrudes from cradle section 120 and is configured to help hold the electrical device to holder 111 by securing the electrical device to cradle section 120.

In this embodiment, electrical interface 1214 (FIG. 12) is not integrated or permanently coupled to holder 1111. Instead, holder 1111 provides an aperture 1125 (FIG. 11) configured to receive electrical interface 1214. Electrical interface 114 can be coupled to a wire 1235 (FIG. 12) and configured to mechanically and electrically couple to the electrical device. In some embodiments, electrical interface 1214 can be an electrical interface sold with electrical device 1090 (FIG. 13). For example, if electrical device 1090 is an Apple iPod®, electrical interface 1214 and wire 1235 can be the connector and wire usually sold with the Apple iPod®. That is, electrical interface 1214 can be a thirty-pin connector coupled to one end of wire 1235 with a USB (universal serial bus) connector (not shown) coupled to the other end of wire 1235.

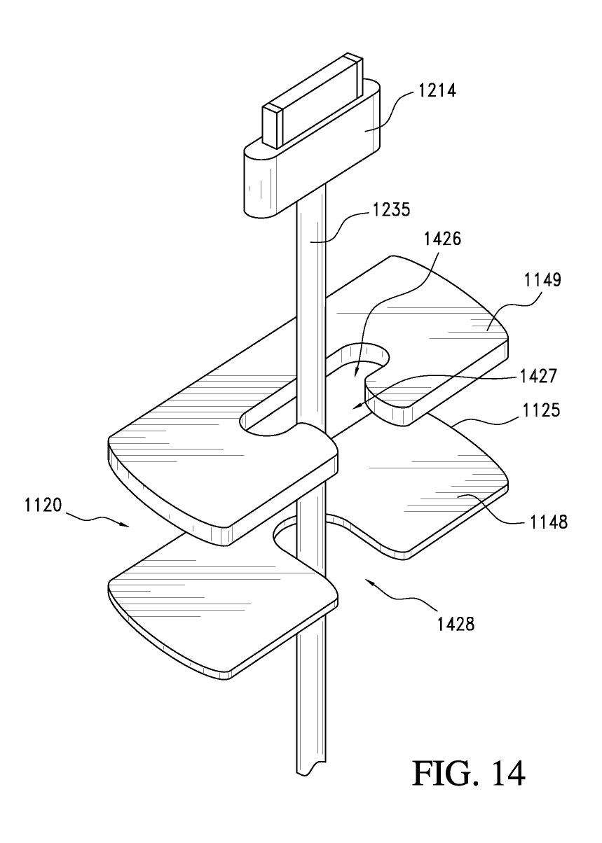

Aperture 1125 (FIG. 11) can be configured to securely integrated electrical interface 1214 into holder 1111. FIG. 14 illustrates an exploded view of an example of cradle section 1120 with electrical interface 1214 and wire 1235, according to the fourth embodiment. In this example, cradle section 1120 can include: (a) a first layer 1148; and (b) a second layer 1149 coupled to the top of first layer 1148. Cradle section 1120 can be configured with this two layer construction to securely and tightly hold electrical interface 1214.

In some examples, aperture 1125 can include: (a) an opening 1426 in second layer 1149; (b) a groove 1427 in second layer 1149 leading from an edge of second layer 1149 to opening 1426; and (c) a groove 1428 in first layer 1148. Grooves 1427 and 1428 can be sized such that a portion of wire 1235 can pass through grooves 1427 and 1428. Grooves 1427 and 1428 are not large enough to permit electrical interface 1214 to pass through or fit inside of grooves 1427 and 1428. In some examples, a width of groove 1427 is substantially equal to a width of groove 1428. Opening 1426 can be configured to receive electrical interface 1214.

When cradle section 1120 is assembled, a first portion of groove 1428 is located adjacent to (e.g., below) opening 1426, and a second portion of groove 1428 is located adjacent (e.g., below) groove 1427. When electrical interface 1214 is placed within aperture 1125, as illustrated in FIG. 12, electrical interface 1214 rests within opening 1426 (FIG. 14) and is supported by first layer 1148 (FIGS. 11 and 14). Wire 1235 can pass through opening 1426 (FIG. 14) and groove 1428 (FIG. 14).

Designing holder 1111 to include aperture 1125 instead of having a built-in electrical interface provides several advantages. For the manufactures, the cost to produce and complexity of electrical accessory 1101 is decreased. For the user, not having a built-in electrical interface allows removal of electrical device 1090 from electrical accessory 1101 while keeping electrical interface 1214 coupled to electrical device 1090. Accordingly, the transfer of video, audio, and/or electrical power to electrical device 1090 can continue uninterrupted when electrical device 1090 is removed from electrical accessory 1101.

Referring again to FIGS. 11-13, similar to previous embodiments, the length of holder 1111 can be adjusted depending on the length of the electrical device coupled to holder 1111. In this embodiment, the length of holder 1111 can be adjusted by moving arm 1122 in relation to arm 1121. In the example illustrated in FIGS. 11-13, arm 1121 includes a groove 1131. Arm 1122 can include a snap section 1132 that is complementary to groove 1131 such that snap section 1132 can be moved up and down groove 1131 to adjust the length of holder 1111 while locking holder 1111 at a length when not being adjusted. In other examples, other length adjustment mechanisms can be employed.

Electrical device 1090 can be inserted into holder 1111 using two methods in some embodiments. In the first method, electrical device 1090 is first coupled to electrical accessory 1101 similar to the coupling of electrical device 290 to electrical accessory 601, as shown in FIG. 8. Then, electrical interface 1214 can first be coupled to holder 1111 as shown in FIG. 13.

In the second method, electrical interface 1214 can be first coupled to electrical device 1090. Afterwards, electrical device 1090 and electrical interface 1214 can be inserted into electrical accessory 1101 together.

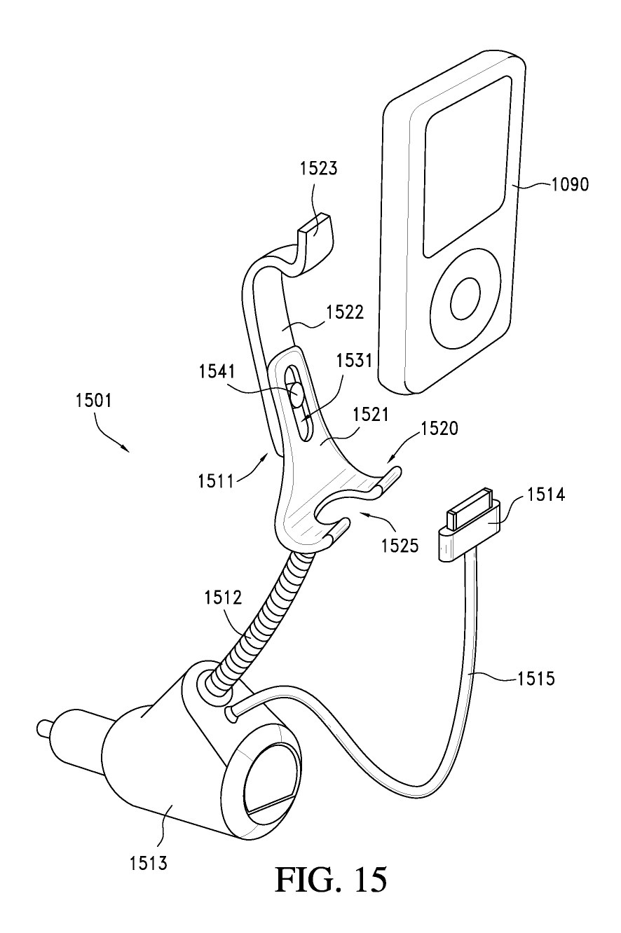

Turning to still another embodiment, FIG. 15 illustrates an isometric view of electrical accessory 1501, according to a fifth embodiment. As illustrated in FIG. 15, electrical accessory 1501 can include: (a) a holder 1511 configured to hold or couple to two or more electrical devices at different times; (b) a connector 1512; (c) a power acquisition unit 1513 configured to receive electrical power from an external power source (e.g., a cigarette lighter); (d) an electrical interface 1514 configured to mechanically and electrically couple to the two or more electrical devices at different times; and (e) a wire 1515 electrically and mechanically coupling electrical interface 1514 to power acquisition unit 1513. Electrical accessory 1501 is merely exemplary and is not limited to the embodiments presented herein. Electrical accessory 1501 can be employed in many different embodiments or examples not specifically depicted or described herein.

Holder 1511 can comprise: (a) a cradle section 1520 configured to couple to the bottom side of the two or more electrical devices (e.g., electrical device 1090 (FIG. 15), electrical device 290 (FIG. 2), and electrical device 2490 (FIG. 24)) at different times; (b) an arm 1521 coupled to cradle section 1520; (c) an arm 1522 adjustably coupled to arm 1521; and (d) a support 1523 coupled to arm 1522 and configured to couple to the top side of the two or more electrical devices at different times. Electrical interface 1514 is not integrated or permanently coupled to holder 1511. Instead, similar to holder 1111 (FIG. 11), holder 1511 provides an aperture 1525 configured to receive electrical interface 1514.

The length of holder 1511 can be adjusted depending on the length of the electrical device coupled to holder 1511. In some examples, arm 1521 can include a groove 1531 extending along at least part of the length of arm 1521. In the same or different embodiments, arm 1522 can include a protrusion 1541 moveably coupled to groove 1531. That is, the length of holder 1511 can be increased or decreased by changing the position of protrusion 1541 in groove 1531.

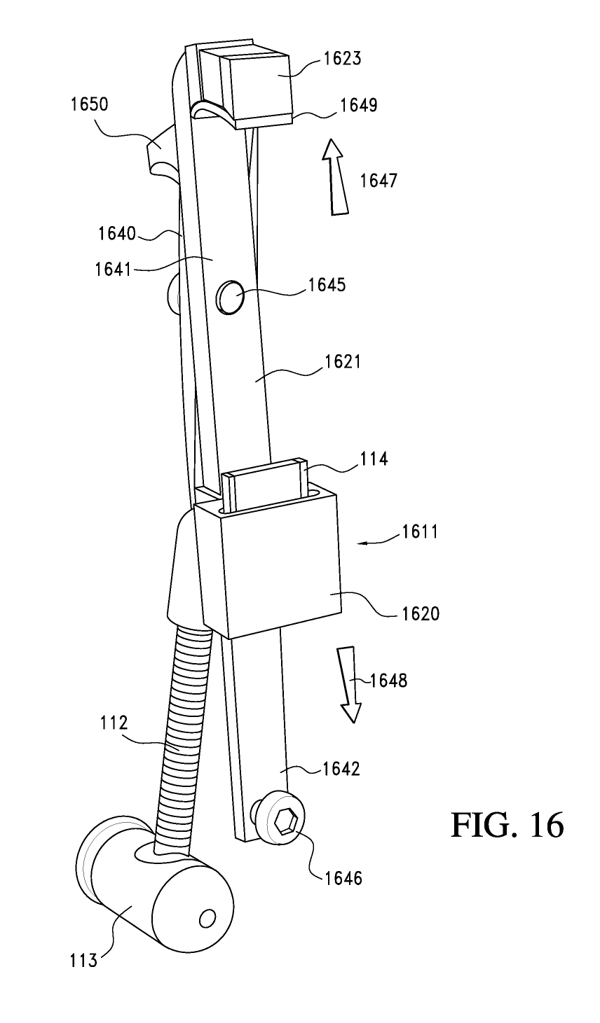

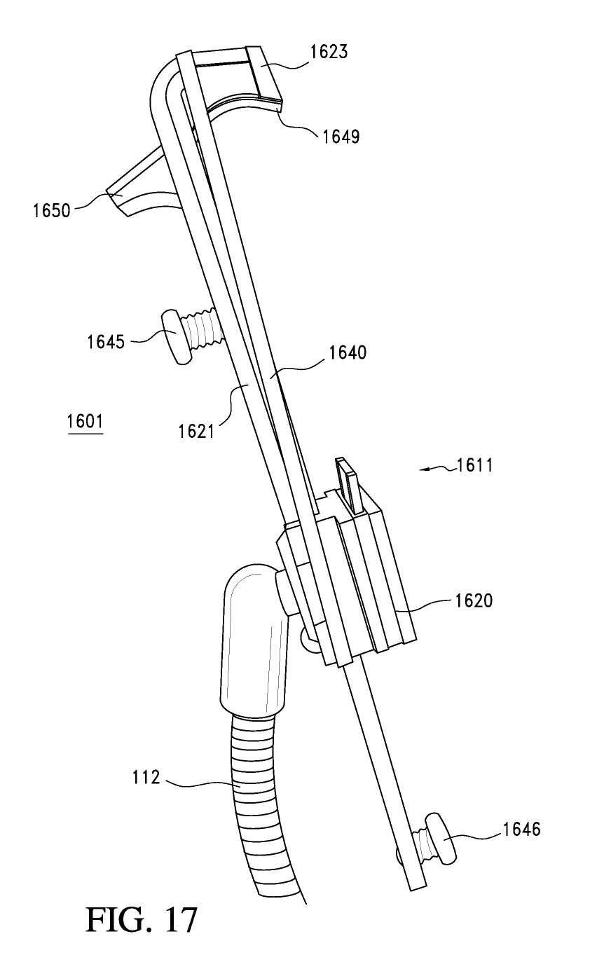

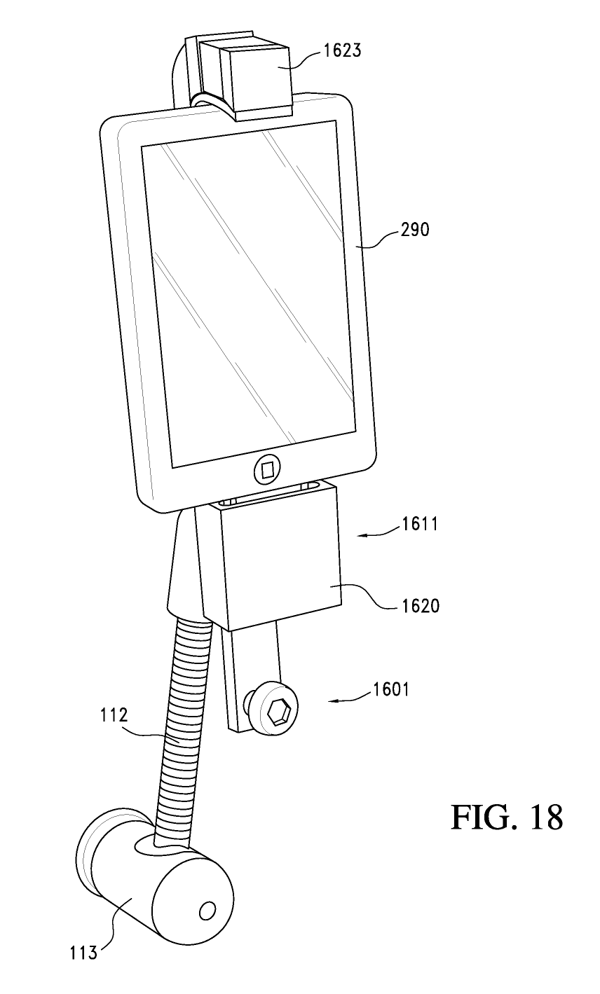

Turning to another embodiment, FIG. 16 illustrates an isometric view of an electrical accessory 1601, according to a sixth embodiment. FIG. 17 illustrates a side view of a portion of electrical accessory 1601, according to the sixth embodiment. FIG. 18 illustrates an isometric view of electrical accessory 1601 holding electrical device 290, according to the sixth embodiment. In some examples, electrical accessory 1601 can be configured to hold two or more electrical devices at different times. In the same or different embodiment, electrical accessory 1601 can be configured for coupling two or more electrical devices to an external power supply at different times. Electrical accessory 1601 is merely exemplary and is not limited to the embodiments presented herein. Electrical accessory 1601 can be employed in many different embodiments or examples not specifically depicted or described herein.

As illustrated in FIGS. 16-18, electrical accessory 1601 can include: (a) a holder 1611 configured to hold or couple to two or more electrical devices at different times; (b) connector 112; (c) power acquisition unit 113 configured to receive electrical power from an external power source (e.g., a cigarette lighter); and (d) electrical interface 114 configured to mechanically and electrically couple to the two or more electrical devices at different times.

Holder 1611 can comprise: (a) a cradle section 1620 coupled to connector 112 and configured to couple to the bottom side of the two or more electrical devices (e.g., electrical device 290 (FIG. 18), electrical device 1090 (FIG. 10), and electrical device 2490 (FIG. 24)) at different times; (b) an arm 1621 coupled to cradle section 1620; (c) a support 1623 with padding 1649 and coupled to arm 1621 and configured to couple to the top side of the two or more electrical devices at different times; (d) a stretch mechanism 1640 coupled to cradle section 1620 and arm 1621; and (e) an offset mechanism 1645. In some examples, electrical interface 114 protrudes from cradle section 1620 and is configured to help hold the electrical device to holder 111 by securing the electrical device to cradle section 1620.

In this embodiment, holder 1611 can hold the electrical device by applying a compression force to the electrical device to retain the electrical device between support 1623 and cradle section 1620. That is, stretch mechanism 1640 is coupled to arm 1621 and cradle section 1620 such that a compression force is applied to any electrical devices placed in holder 1611. Stretch mechanism 1640 in some examples can be an elastic material (e.g., a rubber band or a flexible plastic) coupled between support 1623 and cradle section 1620.

In some examples, arm 1621 is movably coupled to cradle section 1620 such that arm 1621 passes through the interior of cradle section 1620 with a first portion 1641 of arm 1621 extending in a first direction 1647 away from cradle section 1620 or with a second portion 1642 extending away from cradle section 1620 in a second direction 1648 opposite first direction 1647. In these examples, the length of first portion 1641 can be increased and the length of second portion 1642 can be decreased by pulling or pushing first portion 1641 away from cradle section 1620. Conversely, the length of second portion 1642 can be increased and the length of first portion 1641 decreased by pulling or pushing second portion 1642 away from cradle section 1620. In various examples, arm 1621 can have a stop 1646 near or at the end of second portion 1642 to stop arm 1621 from being pulled out of cradle section 1620 and disconnected from the rest of holder 1611.

In the same or different example, holder 1611 is configured such that when support 1623 and cradle section 1620 are not holding an electrical device, the distance between support 1623 and cradle section 1620 is a predetermined default distance (e.g., slightly less than the length of electrical device 2490 (FIG. 24)) or the smallest electrical device that holder 1611 is designed to hold.

Offset mechanism 1645 can be used to provide a third point of contact between electrical device 290 and holder 1611. The other two points of contact are: (1) electrical interface 114/cradle section 1620; and (2) support 1623. In some examples, offset mechanism 1645 can be a screw that can be screwed through arm 1621 until the screw is touching the back of electrical device 290. In other embodiments, other mechanisms can be used instead of a screw (e.g., a pin or a compressive material).

Offset mechanism 1645 can change the angle in which electrical device 290 sits in holder 1611. That is, when offset mechanism 1645 partially supports or abuts electrical device 290, electrical device 290 can be substantially parallel with arm 1621. If offset mechanism 1645 is not used, electrical device 290 can sit in holder 1611 such that the top portion of electrical device 290 is touching arm 1621 and/or the back part of support 1623. In some examples, if offset mechanism 1645 is not used, it could be difficult to form a good electrical coupling between electrical device 290 and electrical interface 114. The use of offset mechanism 1645 is not limited to the embodiment shown in FIG. 16-18. Offset mechanism 1645 can be used in other embodiments of electrical accessories described herein.

The electrical device can be loaded into electrical accessory 1601 using two methods. In the first method, the user pulls support 1623 and arm 1621 away from cradle section 1620. For example, the user can pull support 1623 and arm 1621 using handle 1650. The user can insert the electrical device into electrical interface 114 and release support 1623 and arm 1621. When released, support 1623 and arm 1621 can securely clamp down (i.e., provide a compression force) on the electrical device.

In the second method, the top portion of the electrical device is first used to push support 1623 and arm 1621 away from cradle section 1620. Then, the user can swing the bottom of the electrical device forward to align the electrical device with electrical interface 114. Afterwards, the electrical interface (not shown) on the electrical device can be then inserted into electrical interface 114.

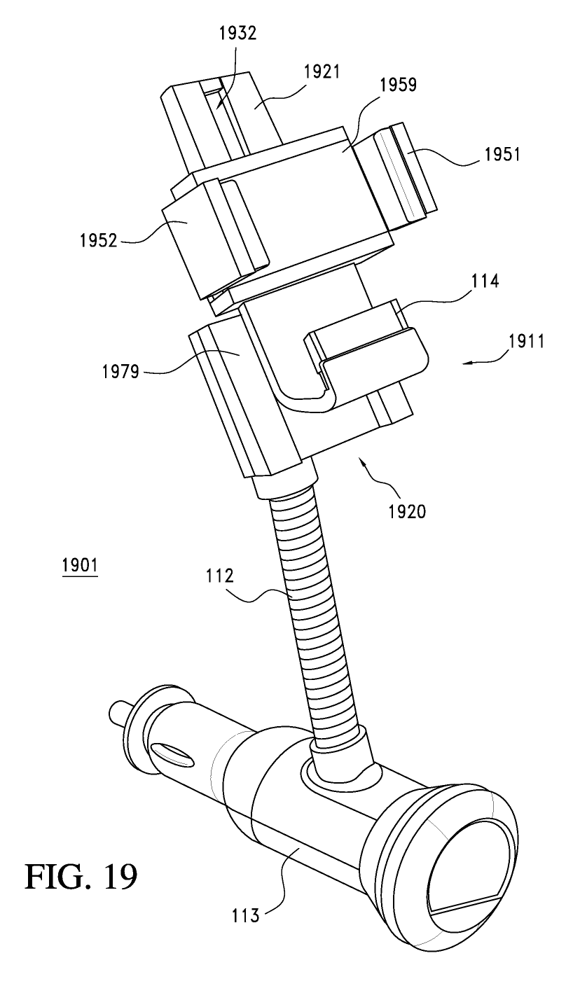

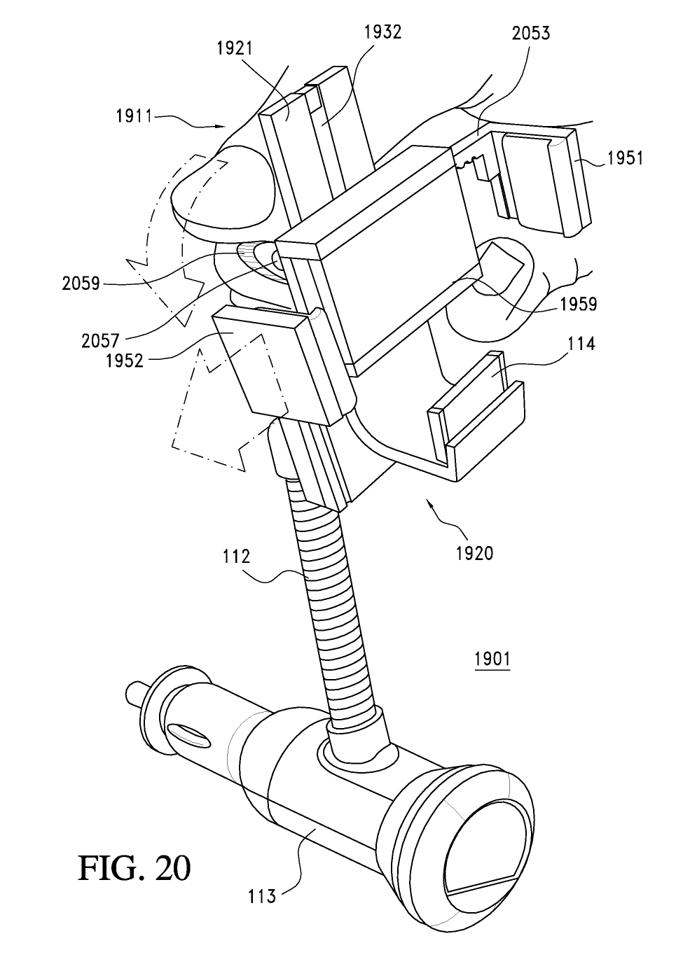

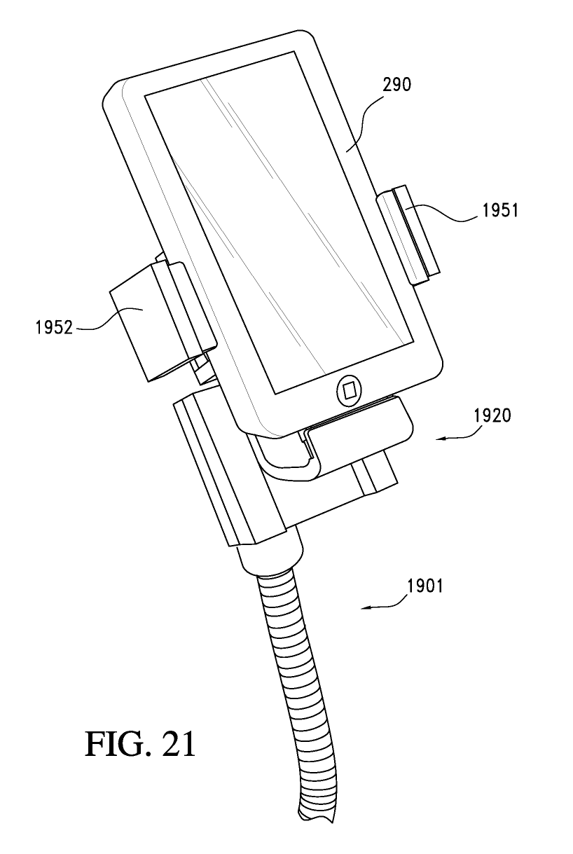

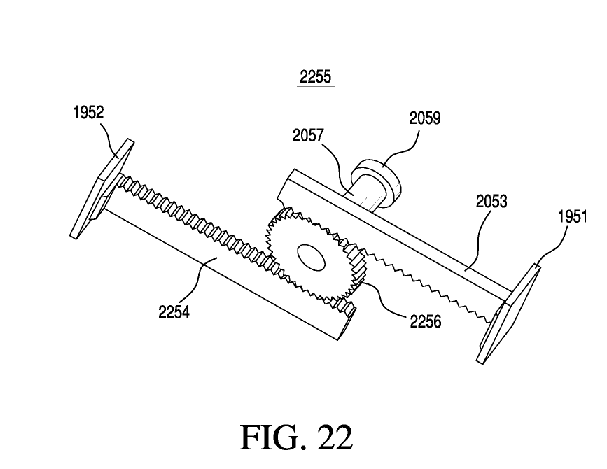

Turning to still an additional embodiment, FIG. 19 illustrates an isometric view of electrical accessory 1901, according to a seventh embodiment. FIG. 20 illustrates another isometric view of electrical accessory 1901, according to the seventh embodiment. FIG. 21 illustrates an isometric view of a portion of electrical accessory 1901 holding electrical device 290, according to the seventh embodiment. FIG. 22 illustrates an isometric view of a gear mechanism 2255 of electrical accessory 1901, according to the seventh embodiment. In some examples, electrical accessory 1901 can be configured to hold two or more electrical devices. In the same or different embodiment, electrical accessory 1901 can be configured for coupling two or more electrical devices to an external power supply at different times. Electrical accessory 1901 is merely exemplary and is not limited to the embodiments presented herein. Electrical accessory 1901 can be employed in many different embodiments or examples not specifically depicted or described herein.

As illustrated in FIGS. 19-22, electrical accessory 1901 can include: (a) a holder 1911 configured to hold or couple to two or more electrical devices at different times; (b) connector 112; (c) power acquisition unit 113 configured to receive electrical power from an external power source; and (d) electrical interface 114 configured to mechanically and electrically couple to the two or more electrical devices. In some examples, electrical interface 114 protrudes from cradle section 1920 and is configured to help couple the electrical device to holder 1911 by securing the electrical device to cradle section 1920.

Holder 1911 can comprise: (a) a cradle section 1920 coupled to connector 112 and configured to couple to the bottom side of the two or more electrical devices (e.g., electrical device 290 (FIG. 21), electrical device 1090 (FIG. 10), and electrical device 2490 (FIG. 24)) at different times; (b) an extension portion/arm 1921 with a slot 1932 and coupled to cradle section 1920; and (c) a gear mechanism 2255 (FIG. 22). Gear mechanism 2255 can be located partially inside of cradle section 1920 and partially extend from cradle section 1920. In some examples, cradle section 1920 can be considered to include a base section 1979 and extension portion/arm 1921

In the embodiment illustrated in FIGS. 19-22, gear mechanism 2255 can be used to adjust the distance between supports 1951 and 1952. Accordingly, the width of holder 1911 can be adjusted depending on the width of the electrical device to be coupled to holder 1911. That is, if a first electrical device (e.g., electrical device 290 (FIG. 21)) has a first width and if a second electrical device (e.g., electrical device 1090 (FIG. 10) or electrical device 2490 (FIG. 24)) has a second width, the width of holder 1911 can be adjusted to be proportional to the first width when coupled to the first electrical device and proportional to the second width when coupled to the second electrical device. That is, when the first electrical device is electrical device 290, a distance between supports 1951 and 1952 is substantially equal to a width of electrical device 290 when electrical accessory 1901 is holding electrical device 290. Similarly, the distance (not shown) between cradle supports 1951 and 1952 is substantially equal to a width of a second electrical device when electrical accessory 1901 is holding the second electrical device.

As shown in FIG. 22, gear mechanism 2255 can include: (a) an arm 2254; (b) support 1952 coupled to a distal end of arm 2254; (c) an arm 2053; (d) support 1951 coupled to a distal end of arm 2053; (e) a gear 2256 mechanically coupled to arms 2254 and 2053; and (f) a pin 2057 with one or more protrusions 2059 (e.g., a knob) and coupled to gear 2256. In some examples, arm 2254 and support 1952 can be considered a first side support. Arm 2053 and support 1951 can be considered a second side support. The first and second side supports along with gear 2256 can be considered a connection section. Pin 2057 and protrusion 2059 can be considered an activation mechanism in some examples.

In some examples, gear 2256 and arms 2053 and 2254 can have teeth. The teeth on arms 2053 and 2254 can be coupled to the teeth on gear 2256 such that when gear 2256 is rotated (using pin 2057), the distance between supports 1951 and 1952 is changed.

In some examples, a user can increase the distance between supports 1951 and 1952 by turning one or more protrusions 2059 clockwise. Turning protrusion(s) 2059 clockwise causes gear 2256 to turn clockwise and move arms 2053 and 2254 away from each other. Similarly, a user can decrease the distance between supports 1951 and 1952 by turning protrusion(s) 2059 counterclockwise. Turning protrusion 2059 counterclockwise causes gear 2256 to turn counterclockwise and move arms 2053 and 2254 toward each other.

In addition to being able to change the distance between supports 1951 and 1952, the distance between connection section 1959 (FIG. 19) of cradle section 1920 and electrical interface 114 can be changed. In some examples, connection section 1959 is mechanically coupled to arm 1921 such that connection section 1959 can be moved up and down the length of slot 1932.

In various embodiments, pin 2057 can be configured to serve a dual function. Pin 2057 and holder 1911 can be configured such that: (a) turning pin 2057 clockwise or counterclockwise causes the distance between supports 1951 and 1952 to change; and (b) pulling pin 2057 away from holder 1911 and moving pin 2057 upward or downward causes the distance between a top of the connection section and electrical interface 114 to change.

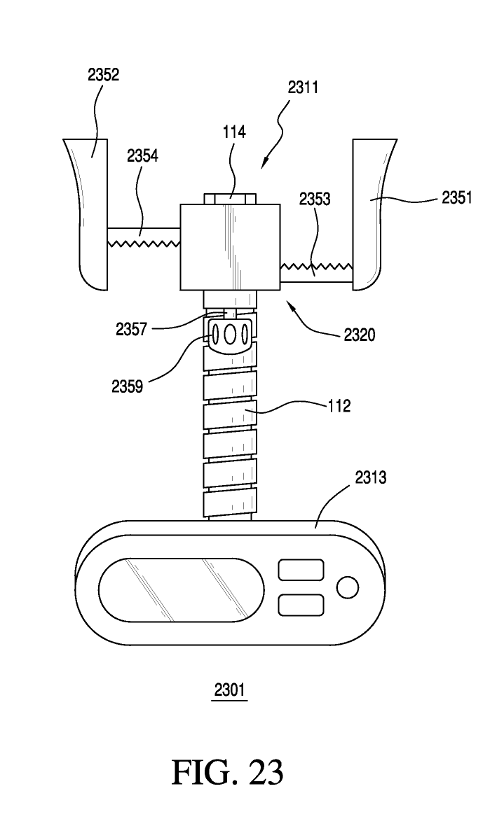

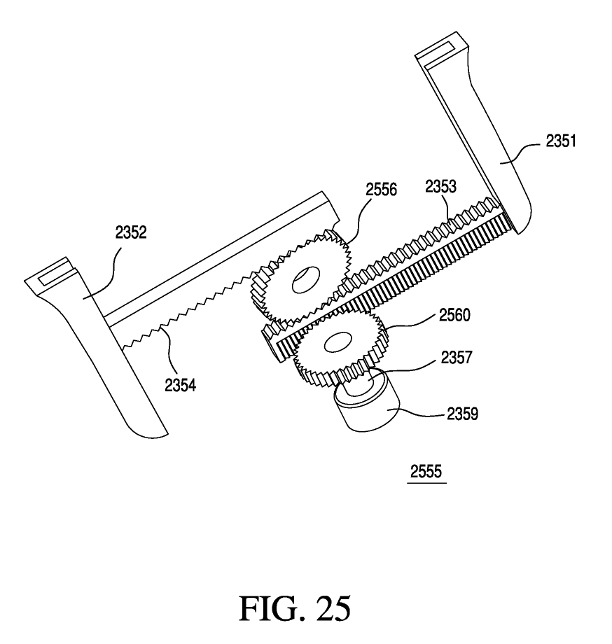

Turning to another embodiment, FIG. 23 illustrates an isometric view of electrical accessory 2301, according to an eighth embodiment. FIG. 24 illustrates an isometric view of electrical accessory 2301 holding electrical device 2490, according to the eighth embodiment. FIG. 25 illustrates an isometric view of a gear mechanism 2555 of electrical accessory 2301, according to the eighth embodiment. Electrical accessory 2301 is merely exemplary and is not limited to the embodiments presented herein. Electrical accessory 2301 can be employed in many different embodiments or examples not specifically depicted or described herein.

As illustrated in FIGS. 23-25, electrical accessory 2301 can include: (a) a holder 2311 configured to hold or couple to two or more electrical devices at different times; (b) connector 112; (c) power acquisition unit 2313 configured to receive electrical power from an external power source; and (d) electrical interface 114 configured to mechanically and electrically couple to the two or more electrical devices. In some examples, electrical interface 114 protrudes from cradle section 2320 and is configured to help hold the electrical device to holder 2311 by securing the electrical device to cradle section 2320.

Holder 2311 can comprise: (a) cradle section 2320 coupled to connector 112 and configured to couple to the bottom side of the two or more electrical devices (e.g., electrical device 290 (FIG. 21), electrical device 1090 (FIG. 10) and electrical device 2490 (FIG. 24)) at different times; and (b) a gear mechanism 2555 (FIG. 25). Gear mechanism 2555 can be located partially inside of cradle section 2320 and partially extend from cradle section 2320.

In the embodiment illustrated in FIGS. 23-25, gear mechanism 2555 can be used to change the distance between supports 2351 and 2352. Gear mechanism 2555 can include: (a) an arm 2354; (b) support 2352 coupled to an end of arm 2354; (c) an arm 2353; (d) support 2351 coupled to an end of arm 2353; (e) a gear 2556 (FIG. 25) mechanically coupled to arms 2354 and 2353; (f) a gear 2560 mechanically coupled to gear 2556; and (g) a pin 2357 with protrusion 2359 and coupled to gear 2560. In some examples, gears 2556 and 2560 and arms 2353 and 2354 can have teeth. The teeth on arms 2353 and 2354 can be coupled to the teeth on gear 2556. The teeth on gear 2556 can also be coupled to the teeth on gear 2560 as illustrated in FIG. 25. Gear mechanism 2555 can be configured such that when protrusion 2359 is rotated, the distance between supports 2351 and 2352 is changed.

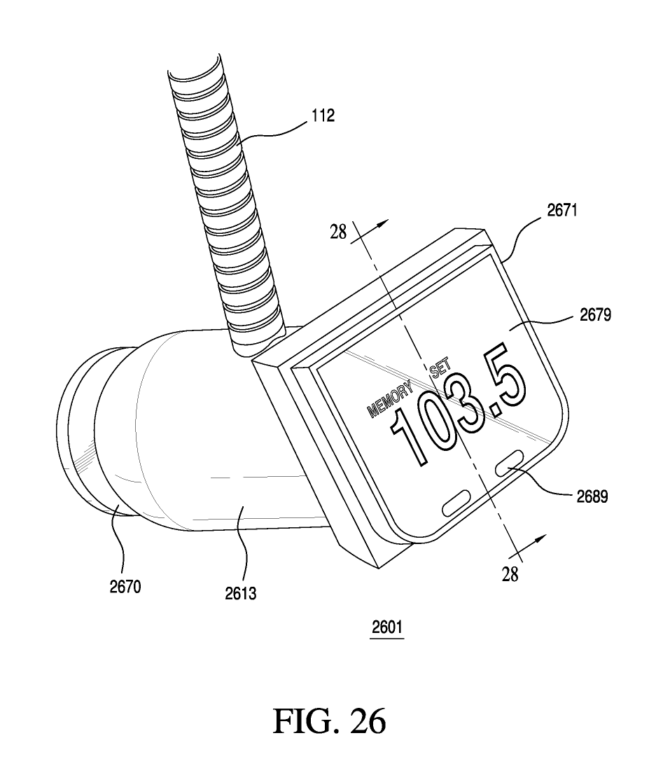

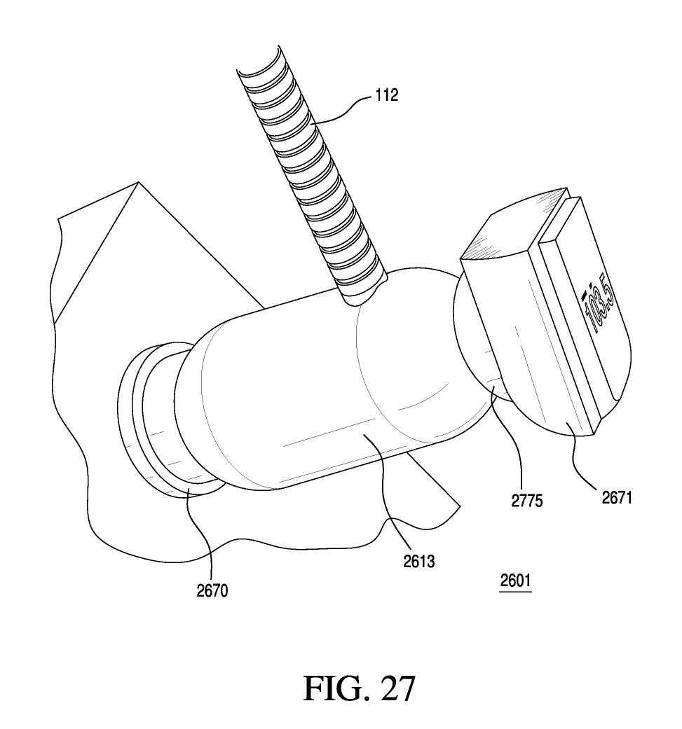

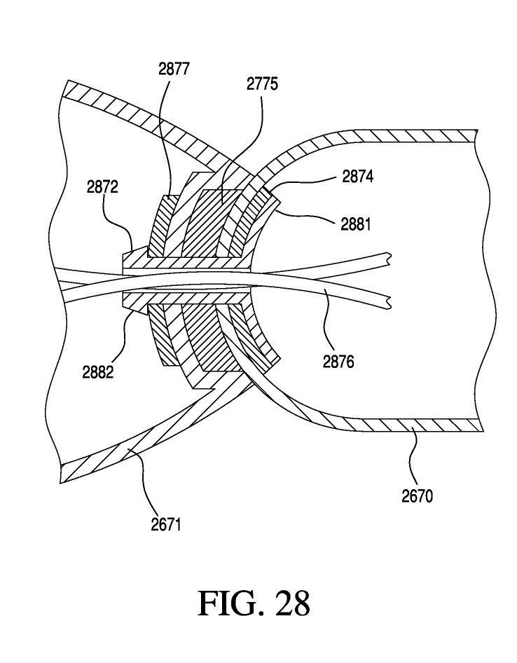

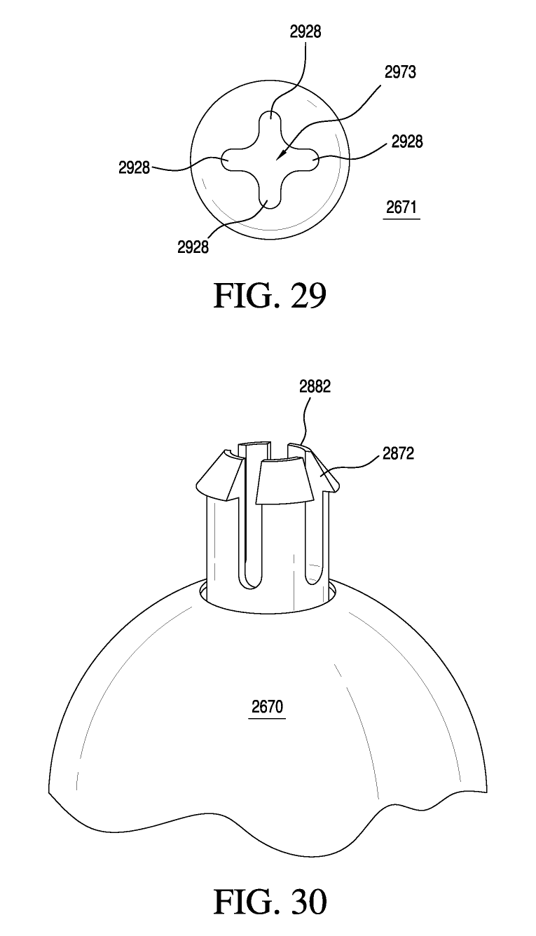

Turning to another example, FIG. 26 illustrates an isometric view of a portion of electrical accessory 2601, according to a ninth embodiment. FIG. 27 illustrates a side view of electrical accessory 2601, according to the ninth embodiment. FIG. 28 illustrates a cut-away view of a power acquisition unit 2613 along line 28-28 (FIG. 26), according to the ninth embodiment. FIG. 29 illustrates a rear view of an electrical module 2671, according to the ninth embodiment. FIG. 30 illustrates a side view of a portion of cigarette lighter module 2670, according to the ninth embodiment. Electrical accessory 2601 is merely exemplary and is not limited to the embodiments presented herein. Electrical accessory 2601 can be employed in many different embodiments or examples not specifically depicted or described herein.

As illustrated in FIGS. 26-30, electrical accessory 2601 can include: (a) a holder (not shown) configured to hold or couple to two or more electrical devices (not shown) at different times; (b) connector 112 coupled to the holder; (c) power acquisition unit 2613 configured to receive electrical power from an external power source (e.g., a cigarette lighter); and (d) an electrical interface (not shown) configured to mechanically and electrically couple to the two or more electrical devices at different times. In many embodiments, the holder of electrical accessory 2601 can be similar or identical to holder 111, 611, 911, 1111, 1511, 1611, 1911, or 2311 of FIGS. 1, 6, 9, 11, 15, 16, 19, and 23, respectively. The electrical interface of electrical accessory 2601 can be similar or identical to electrical interface 114 of FIG. 1.

Power acquisition unit 2613 can include: (a) cigarette lighter module 2670 with an insertion portion 2872 (FIG. 28), insertion portion 2872 can have ends 2881 and 2882; (b) electrical module 2671 with a display 2679; and (c) electrical connectors 2876 (FIG. 28) electrically coupling cigarette lighter module 2670 with electrical module 2671. In some examples, electrical module 2671 can also include a transmitter (not shown) and/or controls 2689 for the transmitter. In the same or different example, electrical module 2671 can include controls (not shown) for the electrical device coupled to electrical accessory 2601.

In this embodiment, the orientation of electrical module 2671 relative to cigarette lighter module 2670 can be adjusted. Being able to adjust the orientation of electrical module 2671 allows a user of electrical accessory 2601 to adjust the viewing angle of display 2679. For example, if electrical accessory 2601 is coupled to a cigarette lighter of a vehicle, the default orientation (e.g., facing straight ahead) of electrical module 2671 may not be easily readable to the driver of the vehicle. Accordingly, the use of adjustable electrical module 2671 allows the driver to change the orientation of electrical module 2671 such that display 2679 is easily readable to the driver.

In some examples, electrical module 2671 has an aperture 2973 (FIG. 29). In some examples, aperture 2973 can be X-shaped and have four wings 2928. In other examples, aperture 2973 can have a different shaped and/or a different number of wings.

Insertion portion 2872 can be placed into aperture 2973 with a washer 2775 (FIGS. 27 and 28) located between electrical module 2671 and cigarette lighter module 2670. Power acquisition unit 2613 can also have washer 2877 (FIG. 28) located between end 2882 and electrical module 2671. Washer 2874 (FIG. 28) can be located between end 2881 and cigarette lighter module 2670. In some examples, washers 2874, 2775, and 2877 are used to decrease friction and provide a tighter coupling between the modules. Washers 2874, 2775, and 2877 can include rubber or foam-like material.

The orientation of electrical module 2671 can be changed by sliding insertion portion 2872 from the center of aperture 2973 (FIG. 29) to one of wings 2928. That is, sliding insertion portion 2872 into one of wings 2928 changes the angle of electrical module 2671 in respect to cigarette lighter module 2670.

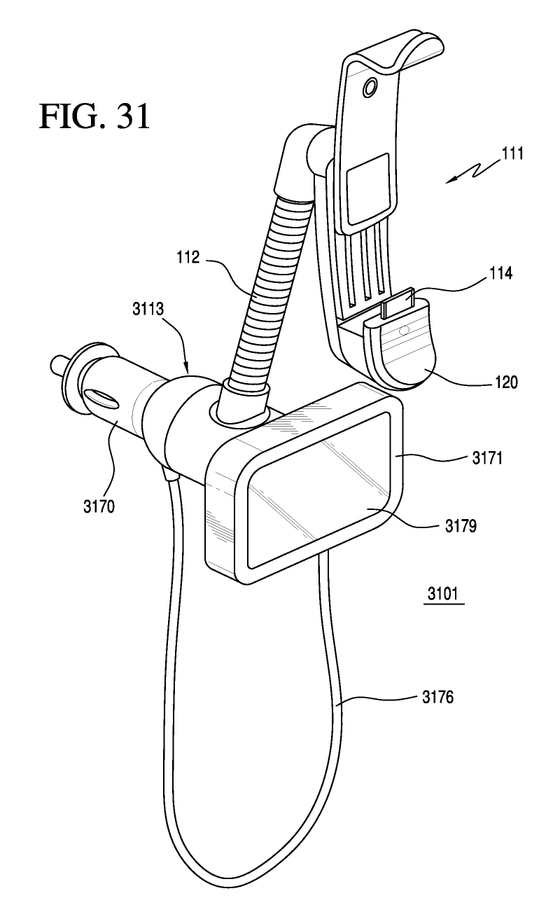

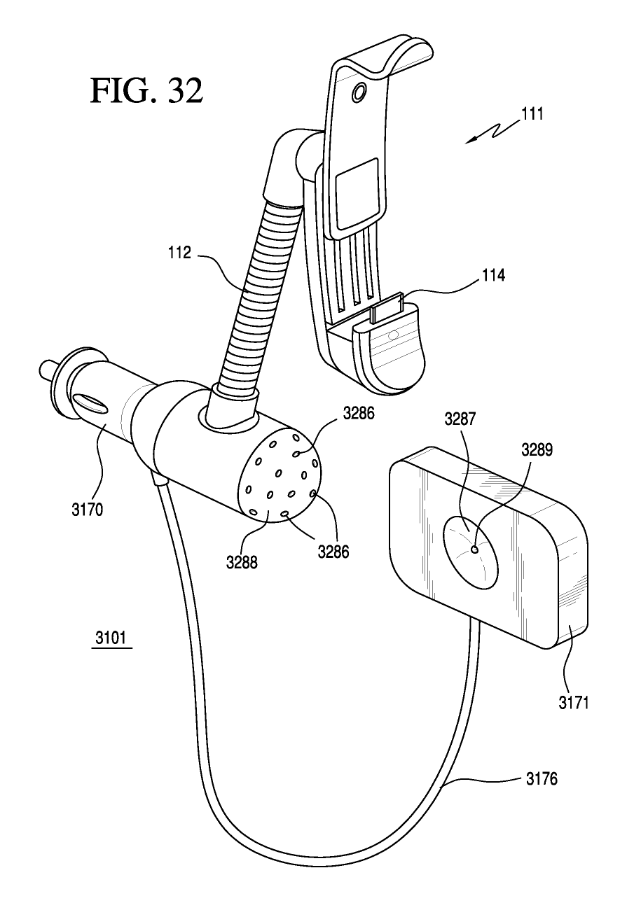

Turning to a further embodiment, FIG. 31 illustrates an isometric view of electrical accessory 3101, according to a tenth embodiment. FIG. 32 illustrates another isometric view of electrical accessory 3101, according to the tenth embodiment. Electrical accessory 3101 is merely exemplary and is not limited to the embodiments presented herein. Electrical accessory 3101 can be employed in many different embodiments or examples not specifically depicted or described herein.

As illustrated in FIGS. 31-32, electrical accessory 3101 can include: (a) holder 111 configured to hold or couple to two or more electrical devices at different times; (b) connector 112 coupled to the holder; (c) a body or power acquisition unit 3113 configured to receive electrical power from an external power source (e.g., a cigarette lighter); and (d) electrical interface 114 configured to mechanically and electrically couple to the two or more electrical devices at different times. In other embodiments, the holder of electrical accessory 2601 can be similar or identical to holder 611, 911, 1111, 1511, 1611, 1911, or 2311 of FIGS. 6, 9, 11, 15, 16, 19, and 23, respectively.

Power acquisition unit 3113 can include: (a) cigarette lighter module 3170 with an end 3288 (FIG. 32); (b) an electrical module 3171 with a display 3179; and (c) electrical connector 3176 electrically coupling cigarette lighter module 3170 with electrical module 3171. In some examples, electrical module 3171 can also include a transmitter (not shown) and/or controls for the transmitter. In the same or different example, electrical module 3171 can include controls (not shown) for the electrical device coupled to electrical accessory 3101.

As shown in FIG. 32, cigarette lighter module 3170 can include dimples 3286 at end 3288. In some examples, dimples 3286 can be similar to the dimples on a golf ball. Electrical module 3171 can include an indentation 3287 with a bump 3289. In some examples, bump 3289 can be located at the center of indentation 3287. In the same or different example, electrical module 3171 can include a magnet (not shown) adjacent to indentation 3287. In some examples, the magnet is located inside the outer surface of electrical module 3171 under indentation 3287.

Electrical module 3171 is removably coupleable to cigarette lighter module 3170 by coupling indentation 3287 and bump 3289 to one of dimples 3286 at end 3288. Electrical module 3171 is held to the metal inside of cigarette lighter module 3170 by the magnet under indentation 3287. The viewing angle of electrical module 3171 can be changed by the user by moving bump 3289 from a first one of dimples 3286 to a second one of dimples 3286. In this embodiment, electrical module 3171 is also removed from cigarette lighter module 3170 so electrical module 3171 can be placed anywhere electrical connector 3176 can reach.

In alternative embodiments, the magnet can be located inside of cigarette lighter module 3170 instead of electrical module 3171. In still further embodiments, a magnet can be located inside of electrical module 3171, and an oppositely polarized magnet can be located inside of cigarette lighter module 3170.

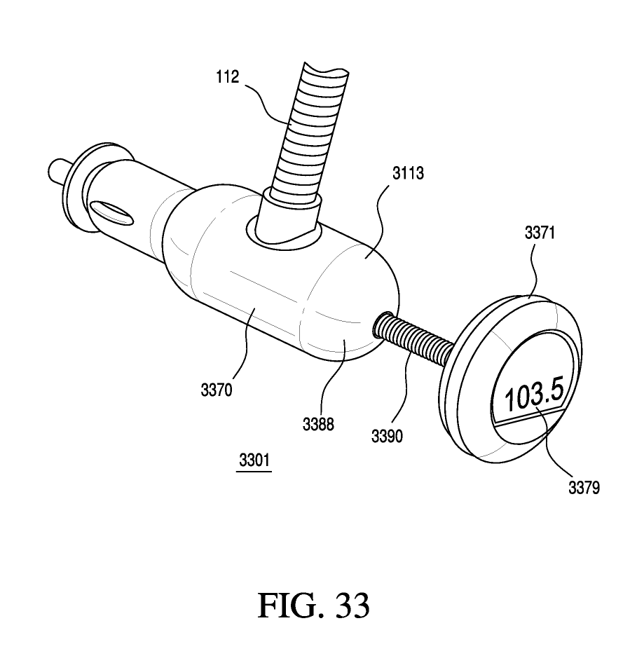

Turning to yet another embodiment, FIG. 33 illustrates an isometric view of a portion of electrical accessory 3301, according to an eleventh embodiment. Electrical accessory 3301 is merely exemplary and is not limited to the embodiments presented herein. Electrical accessory 3301 can be employed in many different embodiments or examples not specifically depicted or described herein.

As illustrated in FIG. 33, electrical accessory 3101 can include: (a) a holder (not shown) configured to hold or couple to one or more electrical devices (not shown) at different times; (b) connector 112 coupled to the holder; (c) power acquisition unit 3113 configured to receive electrical power from an external power source; and (d) an electrical interface (not shown) configured to mechanically and electrically couple to the two or more electrical devices. In some embodiments, the holder of electrical accessory 3301 can be similar or identical to holder 111, 611, 911, 1111, 1511, 1611, 1911, or 2311 of FIGS. 1, 6, 9, 11, 15, 16, 19, and 23, respectively.

Power acquisition unit 3313 can include: (a) cigarette lighter module 3370 with an end 3388; (b) an electrical module 3371 with a display 3379; and (c) connector 3390 electrically coupling cigarette lighter module 3370 with electrical module 3371. In some examples, connectors 3390 and/or 112 can be a gooseneck.

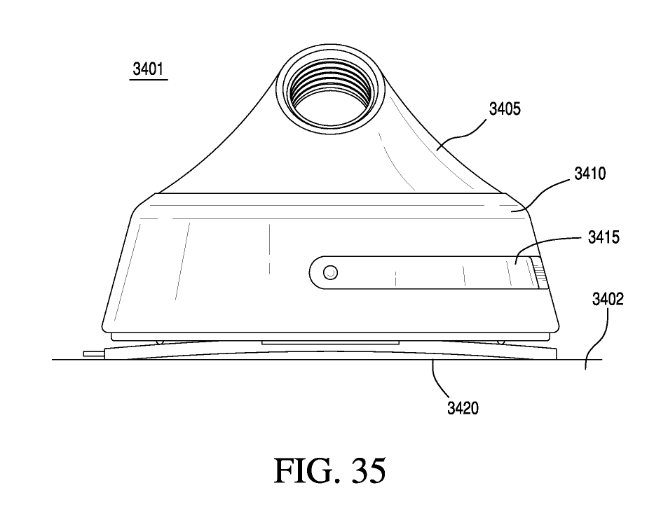

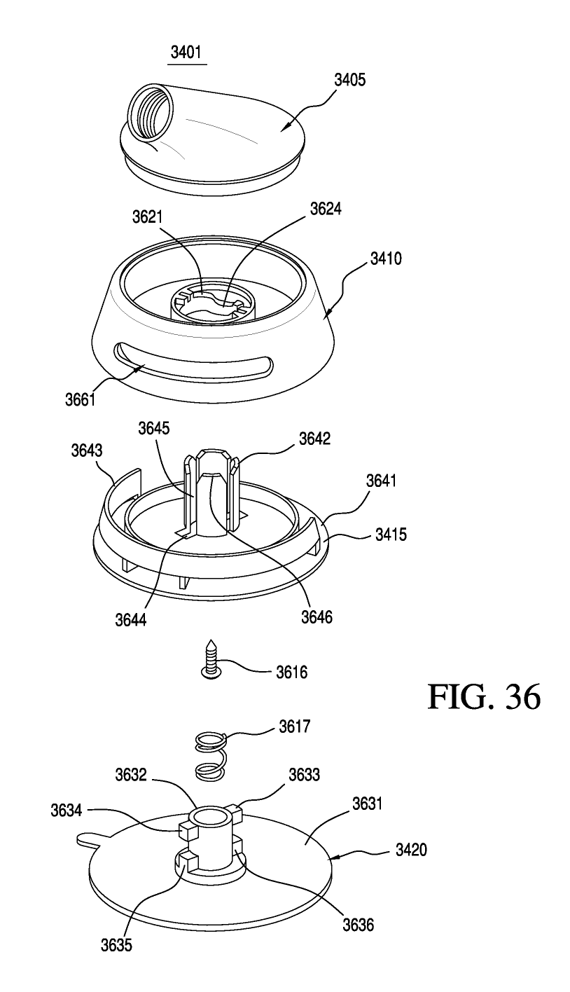

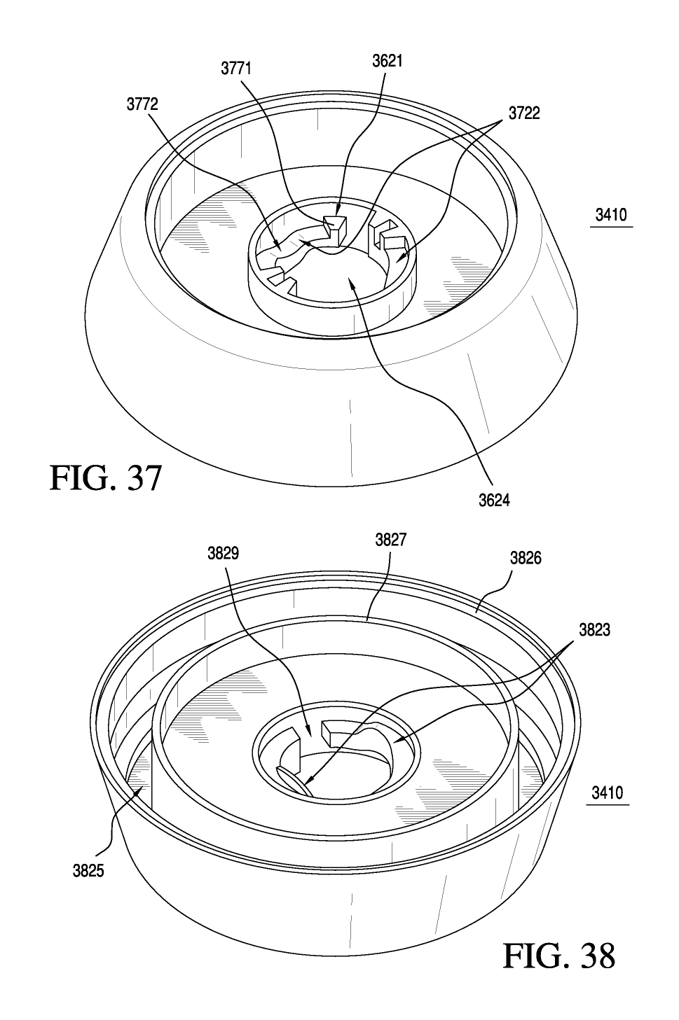

Turning to another embodiment, FIG. 34 illustrates a front view of a coupling mechanism 3401 in a locked position, according to a twelfth embodiment. FIG. 35 illustrates a front view of coupling mechanism 3401 in an unlocked position, according to the twelfth embodiment. FIG. 36 illustrates an exploded view of coupling mechanism 3401, according to the twelfth embodiment. FIG. 37 illustrates a top, back isometric view of a rotational dial 3410 of coupling mechanism 3401, according to the twelfth embodiment. FIG. 38 illustrates a bottom, back isometric view of rotational dial 3410 of coupling mechanism 3401, according to the twelfth embodiment. Coupling mechanism 3401 is merely exemplary and is not limited to the embodiments presented herein. Coupling mechanism 3401 can be employed in many different embodiments or examples not specifically depicted or described herein.

In some examples, an electrical accessory (e.g., electrical accessory 101 of FIG. 1) can have a coupling mechanism 3401, instead of, or in addition to, a power acquisition unit (e.g., power acquisition unit 113 (FIG. 1)). For example, region 3405 of coupling mechanism can be configured to couple to connector 112 (FIG. 12). In other embodiments, power acquisition unit 113 (FIG. 1) can include coupling mechanism 3401 instead of end portion 151 (FIG. 1). In still other embodiments, coupling mechanism 3401 can be coupled to other types of devices, modules, and/or apparatuses.

Referring to FIGS. 34-38, in various embodiments, coupling apparatus or mechanism 3401 can include: (a) a top housing 3405; (b) a rotational dial 3410; (c) a support base 3415; (d) a connecting mechanism 3616 (e.g., a screw or pin) (FIG. 36); (e) an elastic mechanism 3617 (e.g., a spring) (FIG. 36); and (f) a suction cup 3420. In many examples, coupling mechanism 3401 is configured such that rotational dial 3410 can be rotated relative to support base 3415 and/or suction cup 3420 to vacuum attach (i.e., lock) suction cup 3420 to a surface 3402.

In one example, when coupling mechanism 3401 is resting on surface 3402, and when a user begins to rotate rotational dial 3410 relative to support base 3415 in a first direction (e.g., counterclockwise), the rotational movement first pushes suction cup 3420 downward to dispel air that is trapped under suction cup 3420. After pushing suction cup 3420 downward, the rotational movement can cause a reversal in the direction of the movement of suction cup 3420, and the center of suction cup 3420 is pulled upward (i.e., inward towards the rest of coupling mechanism 3401) to create a vacuum between suction cup 3420 and surface 3402. In various embodiments, the vacuum created between coupling mechanism 3401 and surface 3402 is stronger than the vacuum between a traditional suction cup and a surface because the first downward movement of the suction cup expels the air from between suction cup 3420 and surface 3402, thus allowing for a stronger vacuum to be formed between suction cup 3420 and surface 3402.

In some examples, as shown in FIG. 36, suction cup 3420 can have: (a) a suction portion 3631 and (b) a stem 3632 protruding from suction portion 3631. Stem 3632 can have two or more wings 3633, 3634, 3635, and 3636.

Support base 3415 can include: (a) a bottom portion 3641; (b) a stem 3642 protruding from bottom portion 3641; and (c) at least one cam 3643 also protruding from bottom portion 3641. Stem 3642 can have one or more slots 3644 and 3645.

In various examples, cam 3643 can have an indicator 3447. In some examples, indicator 3447 can indicate whether coupling mechanism is in a locked position (FIG. 34) or an unlocked position (FIG. 35). That is, indicator 3447 can provide information to a user regarding how rotational dial 3410 needs to be moved or rotated to attach coupling mechanism 3401 to surface 3402.

Rotational dial 3410 can include: (a) an outer ring 3826 (FIG. 38) with a slot 3661 for indicator 3447; (b) an inner ring 3827 (FIG. 38); and (c) a cam mechanism 3621 within inner ring 3827. Cam mechanism 3621 can have one or more retracting cams 3722 and one or more compression cams 3823 (FIG. 38). Cam mechanism 3621 can be adjacent to an aperture 3624 in rotational dial 3410 in some examples.

Additionally, a slot 3825 (FIG. 38) can be located between outer ring 3826 (FIG. 38) and inner ring 3827 (FIG. 38) in various embodiments. Cam 3643 can be located in slot 3825 in some examples, when rotational dial 3410 is mechanically coupled to support base 3415.

In some examples, connecting mechanism 3616 (FIG. 36) can be used to couple top housing 3405, rotational dial 3410, and support base 3415 together. When top housing 3405, rotational dial 3410, and support base 3415 are coupled together, stem 3642 (FIG. 36) is inside of aperture 3624, and cam 3643 is inside of slot 3825. In many embodiments, connecting mechanism 3616 can abut a surface inside of stem 3642 and be coupled to (e.g., screwed into) a hole in top housing 3405.

Suction cup 3420 is removable from the rest of coupling mechanism 3401. For example, if suction cup 3420 wears out or is damaged, suction cup 3420 can be removed from coupling mechanism 3401 and replaced with a new suction cup.

In some examples to couple suction cup 3420 with the rest of coupling mechanism 3401, wings 3633 and 3634 are inserted into slots 3644 in support base 3415 and then into slots 3829 in rotational dial 3410. Elastic mechanism 3617 can be placed between suction cup 3420 and rotational dial 3410. In various embodiments, one end of elastic mechanism 3617 can abut the same surface of stem 3642 that connecting mechanism 3616 abuts. The second end of elastic mechanism 3617 can abut stem 3632.

After wings 3633 and 3634 are inserted into slots 3644 in support base 3415 and slots 3829 in rotational dial 3410, suction cup 3420 can be semi-permanently coupled to the rest of coupling mechanism 3401. In some examples, suction cup 3420 can be rotated (e.g., counterclockwise) while an upward force is applied to stem 3632 so wings 3633 and 3634 are lifted over ridge 3771 into regions 3772. Afterward wings 3633 and 3634 are abutted on the bottom by region 3772 of cam mechanism 3621 and on the top by edge 3646 of stem 3642. Wings 3633 and 3634 can be rotated in region 3772.

Suction cup 3420 can be removed (i.e., uncoupled) from the rest of coupling mechanism 3401 by rotating (e.g., clockwise) suction cup 3420 while an upward force is applied to stem 3632 so wings 3633 and 3634 are lifted over ridge 3771 into slot 3829. Stem 3632 can then be pulled out of slots 3644 in support base 3415 and out of slots 3829 in rotational dial 3410.

As previously discussed, a vacuum between coupling mechanism 3401 and surface 3402 can be created by rotating rotational dial 3410 relative to suction cup 3420 and support base 3415. That is, a user can begin rotating rotational dial 3410 relative to suction cup 3420 and support base 3415 in a first direction (e.g., counterclockwise), which causes a downward movement of wings 3633 and 3634 relative to cam 3722, forcing stem 3632 downward and thus, pushing out air that is trapped between suction portion 3631 and surface 3402. Because of the curvature and features of cam mechanism 3621, as the user continues to rotate the rotational dial in the first direction, the direction of the movement of stem 3632 is reversed, and stem 3632 is pulled upward or inward (i.e., toward the rest of coupling mechanism 3401). Pulling stem 3632 upward or inward creates the vacuum between suction portion 3631 and surface 3402 that holds coupling mechanism 3401 to surface 3402.

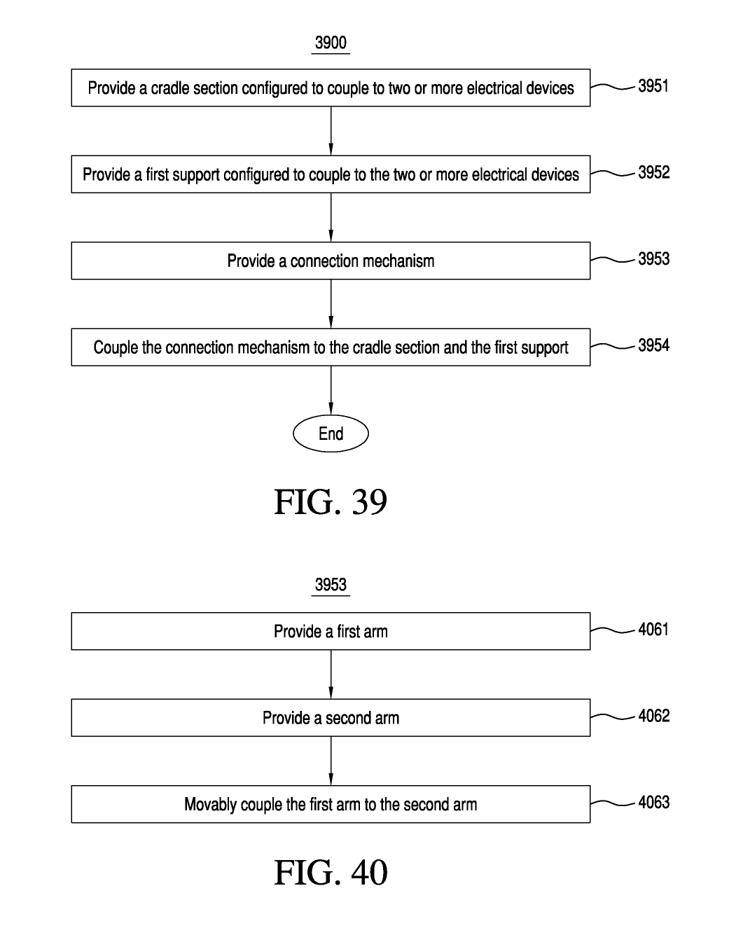

Turning to yet still another embodiment, FIG. 39 illustrates a flow chart for an embodiment of a method 3900 of providing an electrical accessory for holding two or more electrical devices. Method 3900 is merely exemplary and is not limited to the embodiments presented herein. Method 3900 can be employed in many different embodiments or examples not specifically depicted or described herein.

Method 3900 in FIG. 39 can include an activity 3951 of providing a cradle section configured to couple to the two or more electrical devices. For example, the cradle section can be similar or identical to cradle section 120, 620, 920, 1120, 1520, 1620, 1920, or 2320 of FIGS. 1, 6, 9, 11, 15, 16, 19, and 23, respectively.

Method 3900 of FIG. 39 continues with an activity 3952 of providing a first support configured to couple to the two or more electrical devices. For example, the first support can be similar or identical to support 123, 623, 923, 1123, 1523, or 1623 of FIGS. 1, 6, 9, 11, 15, and 16, respectively. The first support can also be similar or identical to side supports 1951 and 1952 of FIG. 19 or side supports 2351 and 2352 of FIG. 23.

Next, method 3900 of FIG. 39 includes an activity 3953 of providing a connection mechanism. FIG. 40 illustrates a flow chart for an embodiment of activity 3953 of providing a connection mechanism, according to an embodiment.

Referring to FIG. 40, activity 3953 includes a first process 4061 of providing a first arm. For example, the first arm can be similar or identical to arm 121, 921, 1121, or 1521 of FIGS. 1, 9, 11, and 15, respectively.

Activity 3953 also includes a process 4062 of providing a second arm. For example, the second arm can be similar or identical to arm 122, 922, 1122, or 1522 of FIGS. 1, 9, 11, and 15, respectively. Process 4062 can be performed concurrently with or before process 4061 in some examples.

Next, activity 3953 continues with a process 4063 of movably coupling the first arm to the second arm. For example, the coupling of the first arm to the second arm can be similar or identical to the coupling of arm 121 to arm 122 in FIG. 1, the coupling of arm 921 to arm 922 in FIG. 9, the coupling of arm 1121 to arm 1122 in FIG. 11, or the coupling of arm 1521 to arm 1522 in FIG. 15. After process 4063, activity 3953 is complete in this example.

In other examples, providing a connection mechanism in activity 3953 can include providing arm 612 of FIG. 6. In still further examples, providing a connection mechanism can include arm 1621 and stretch mechanism 1640 of FIG. 16. In yet additional examples, providing a connection mechanism can include providing gear mechanism 2255 or 2555 of FIGS. 22 and 25, respectively.

Referring again to FIG. 39, method 3900 can include an activity 3954 of coupling the connection mechanism to the cradle section and the first support. In some examples, the coupling the connection mechanism to the cradle section and the first support form a holder. The holder formed by coupling the connection mechanism to the cradle section and the first support can be similar or identical to holder 111, 611, 911, 1111, 1511, 1611, 1911, or 2311 of FIGS. 1, 6, 9, 11, 15, 16, 19, and 23, respectively.

In some examples, coupling the connection mechanism to the cradle section and the first support can include coupling the connection mechanism to the cradle section and the first support such that a length of the holder is changed by moving the second arm relative to the first arm.

In some examples, the order of activities 3951-3953 can be changed. For example, activity 3953 can occur concurrently with or before activities 3951 and 3952.

Although the invention has been described with reference to specific embodiments, it will be understood by those skilled in the art that various changes may be made without departing from the spirit or scope of the invention. For example, it will be readily apparent that any of the holders disclosed herein can include an aperture (similar to aperture 1125 (FIG. 11) or 1525 (FIG. 5)) instead of a permanently attached electrical interface. Additional examples of such changes have been given in the foregoing description. Accordingly, the disclosure of embodiments is intended to be illustrative of the scope of the invention and is not intended to be limiting. It is intended that the scope of the invention shall be limited only to the extent required by the appended claims. To one of ordinary skill in the art, it will be readily apparent that the electrical accessory, the apparatus, the electrical device and method of providing discussed herein may be implemented in a variety of embodiments, and that the foregoing discussion of certain of these embodiments does not necessarily represent a complete description of all possible embodiments. Rather, the detailed description of the drawings, and the drawings themselves, disclose at least one preferred embodiment, and may disclose alternative embodiments.

All elements claimed in any particular claim are essential to the embodiment claimed in that particular claim. Consequently, replacement of one or more claimed elements constitutes reconstruction and not repair. Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims, unless such benefits, advantages, solutions, or elements are stated in such claim.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A coupling device configured to couple to a surface, the coupling device comprising:
a first housing;
a rotational dial with a first aperture and mechanically coupled to the first housing, the rotational dial comprising a cam mechanism adjacent to the first aperture;
a support base comprising a first stem with a second aperture, the first stem is located inside the first aperture, the first stem having a second aperture;
a suction cup coupled to at least one of the rotational dial or the support base, the suction cup comprising:
a suction portion; and
a second stem located inside of the second aperture; and
an elastic mechanism located at least partially between the support base and the second stem of the suction cup,
wherein:
the coupling device is configured such that the rotational dial can be rotated relative to at least the suction cup to create a vacuum between the suction portion of the suction cup and the surface.

2. The coupling device of claim 1, wherein:
the second stem of the suction cup comprises one or more wings; and
the one or more wings of the second stem are coupled to at least one of the first stem of the support base or the cam mechanism of the rotational dial such that the suction cup is coupled to at least one of the rotational dial or the support base and such that the rotational dial can be rotated relative to at least the suction cup to create the vacuum between the suction portion and the surface.

3. The coupling device of claim 1, wherein:
the suction cup is removably coupled to at least one of the rotational dial or the support base.

4. The coupling device of claim 1, wherein:
the coupling device is configured such that the suction cup can be moved downward relative to the surface to dispel air between the suction portion of the suction cup and the surface before creating the vacuum between the suction portion of the suction cup and the surface.

5. The coupling device of claim 1, wherein:
the elastic mechanism comprises a spring.

6. The coupling device of claim 1, wherein:
the cam mechanism of the rotational dial comprises an indicator; and
the indicator is configured to indicate whether the coupling mechanism is in a locked position or an unlocked position.

7. An electrical accessory for holding two or more electrical devices, each of the two or more electrical devices having a top side and a bottom side opposite the top side, the electrical accessory comprising:
a holder configured to couple to the two or more electrical devices at different times, the holder comprising:
a cradle section configured to removably couple to the bottom side of the two or more electrical devices;
a first arm coupled to the cradle section;
a second arm movably coupled to the first arm; and
a first support coupled to the second arm and configured to couple to the top side of the two or more electrical devices,
wherein:
a length of the holder is a distance between the cradle section and the first support;
the holder is configured such that the length of the holder is adjusted by moving the second arm relative to the first arm;
the length of the holder is substantially equal to a length of a first electrical device of the two or more electrical devices when the holder is removably coupled to the first electrical device of the two or more electrical devices;
the length of the holder is substantially equal to a length of a second electrical device of the two or more electrical devices when the holder is removably coupled to the second electrical device of the two or more electrical devices;
the first arm has a first end coupled to the cradle section and a second end opposite the first end;
the first arm comprises one or more first coupling mechanisms;
the one or more first coupling mechanisms extend in the first arm at least partially from the first end to the second end;
the second arm has one or more second coupling mechanisms; and
the one or more second coupling mechanisms are coupled to the one or more first coupling mechanisms the length of the holder is adjusted by moving one of the first or second coupling mechanism with respect to a different one of the first or second coupling mechanism.

8. The electrical accessory of claim 7, wherein:
the cradle section has an aperture;
the aperture is configured to receive and hold an electrical interface; and
the electrical interface is configured to removably couple to the two or more electrical devices.

9. The electrical accessory of claim 8, wherein:
the electrical interface is permanently coupled to the cradle section.

10. The electrical accessory of claim 8, wherein:
the electrical interface is removably coupled to the cradle section.

11. The electrical accessory of claim 8, wherein:
the cradle section comprises:
a first layer with a first opening and a first groove; and
a second layer with a second groove;
the first groove runs from an edge of the first layer to the first opening;
a width of the first groove is substantially equal to a width of the second groove;
the first layer is coupled to the second layer such that a first portion of the second groove is located adjacent to the first opening and such that a second portion of the second groove is located adjacent to the first groove; and
the aperture comprises the first groove, the second groove, and the first opening.

12. The electrical accessory of claim 7, further comprising:
a power acquisition unit configured to receive electrical power from an external power source; and
a gooseneck connector coupling the power acquisition unit to the holder.

13. The electrical accessory of claim 7, further comprising:
a body comprising a suction cup; and
a gooseneck connector configured to couple the body to the holder,
wherein:
the suction cup is configured to hold the electrical accessory to a flat surface.

14. The electrical accessory of claim 7, further comprising:
a coupling device coupled to the cradle and configured to couple to a surface, the coupling device comprising:
a first housing;
a rotational dial with a first aperture and mechanically coupled to the first housing, the rotational dial comprising a cam mechanism adjacent to the first aperture;
a support base comprising a first stem with a second aperture, the first stem is located inside the first aperture, the first stem having a second aperture;
a suction cup coupled to at least one of the rotational dial or the support base, the suction cup comprising:
a suction portion; and
a second stem located inside of the second aperture; and
an elastic mechanism located at least partially between the support base and the second stem of the suction cup,
wherein:
the coupling device is configured such that the rotational dial can be rotated relative to at least the suction cup to create a vacuum between the suction portion of the suction cup and the surface.

15. An electrical accessory for holding two or more electrical devices, the electrical accessory comprising:
a holder configured to couple to the two or more electrical devices at different times, the holder comprising:
a cradle section comprising an electrical coupling;
a first side support with a proximal end and a distal end opposite the proximal end of the first side support;
a second side support with a proximal end and a distal end opposite the proximal end of the second support;
one or more gears coupled to the first side support and the second side support; and
an activation mechanism coupled to the one or more gears,
wherein:
the holder is configured such that a first electrical device of the two or more electrical devices is held between the cradle section, the first side support, and the second side support when the holder is removably coupled to the first electrical device of the two or more electrical devices; and
the one or more gears are configured such that a user can use the activation mechanism to turn the one or more gears and cause a distance between the distal end of the first side support and the distal end of the second side support to change.

16. The electrical device of claim 15, wherein:
the one or more gears comprise:
a first gear coupled to the first side support, the second side support, and the activation mechanism; and
the activation mechanism comprises a knob.

17. The electrical device of claim 15, wherein:
the one or more gears comprise:
a first gear coupled to the first side support and the second side support; and
a second gear coupled to the first gear and the activation mechanism; and
the activation mechanism comprises a knob.

18. The electrical device of claim 15, wherein:
the cradle section comprises:
a base section;
an extension portion extending away from the base section; and
a connection section coupled to the extension portion such that the connection section can be moved in a first direction in relation to the base section; and
the connection section comprises the first side support, the second side support, and the one or more gears.

19. The electrical device of claim 18, wherein:
the holder is configured such that the distal end of the first side support moves in a second direction and such that the distal end of the second side support moves in a third direction; and
the second and third directions are substantially parallel to each other and are substantially perpendicular to the first direction.

20. A method of providing an electrical accessory for holding two or more electrical devices, the method comprising:
providing a cradle section configured to couple to the two or more electrical devices at different times;
providing a connection mechanism;
providing a first support configured to removably couple to the two or more electrical devices; and
coupling the cradle section to the connection mechanism and the first support,
wherein:
a holder comprises the cradle section, the connection mechanism, and the first support;
a length of the holder is a distance between the cradle section and the first support;
providing the connection mechanism comprises:
providing a first arm;
providing a second arm; and
movably coupling the first arm to the second arm; and
coupling the cradle section to the connection mechanism and the first support comprises:
coupling the cradle section to the connection mechanism and the first support such that the length of the holder is changed by moving the second arm relative to the first arm.
